(19) United States
(12) Patent Application Publication
(10) Pub. No.: US 2026/0206443 A1
(43) Pub. Date: Jul. 16, 2026

(54) DISPLAY DEVICE AND ELECTRONIC DEVICE

(71) Applicant: Samsung Display Co., Ltd., Yongin-si (KR)

(72) Inventors: Jin Seon KWAK, Yongin-si (KR); Jang Mi KANG, Yongin-si (KR); Keon Min OH, Yongin-si (KR); Yun Jang PYUN, Yongin-si (KR)

(73) Assignee: Samsung Display Co., Ltd., Yongin-si (KR)

(21) Appl. No.: 19/426,325

(22) Filed: Dec. 19, 2025

(30) Foreign Application Priority Data
Jan. 15, 2025 (KR) 10-2025-0005844

(51) Int. Cl. H10K 59/131

(52) U.S. Cl. CPC H10K 59/131

(57) ABSTRACT

A display device in includes a display panel including a display area and a non-display area; a data driver in the non-display area of the display panel and connected to a data line in the display area; a gamma circuit in the non-display area of the display panel and connected to the data driver; and a first connection line connecting the gamma circuit with the data driver. The data driver includes a data processing circuit, and a data output circuit connected to the data processing circuit and the data line. The data output circuit and the gamma circuit are arranged in different rows in the non-display area. The gamma circuit and the data output circuit active area connected with each other by the first connection line. The first connection line at least partially overlaps the data processing circuit.

This application claims priority from Korean Patent Application No. 10-2025-0005844 filed on Jan. 15, 2025 in the Korean Intellectual Property Office, the disclosure of which is incorporated herein by reference in its entirety.

### BACKGROUND

Some example embodiments relate to a display device, and more particularly, to a display device in which a data output circuit can be formed on a high-resolution display panel without reducing a channel width, and in which circuits spaced apart from each other can be easily connected with each other. Alternatively or additionally, some example embodiments relate to an electronic device.

An organic light-emitting diode (OLED) display, unlike a liquid-crystal display, is self-luminous. Accordingly, an OLED display does not require or utilize a separate light source and thus the OLED display can be made lighter and thinner. Alternatively or additionally, an OLED display has high-quality characteristics such as low power consumption, high luminance and fast response speed, and thus is attracting attention as the next generation display.

### SUMMARY

Some example embodiments may provide a display device in which a data output circuit can be formed on a high-resolution display panel without reducing a channel width. Alternatively or additionally, some example embodiments provide a display device in which circuits spaced apart from each other can be easily connected with each other. Alternatively or additionally, some example embodiments provide an electronic device.

According to some example embodiments, there is provided a display device including a display panel comprising a display area and a non-display area, a data driver in the non-display area of the display panel and connected to a data line in the display area, a gamma circuit in the non-display area of the display panel and connected to the data driver, and a first connection line connecting the gamma circuit with the data driver. The data driver comprises a data processing circuit, and a data output circuit connected to the data processing circuit and the data line, and the data output circuit and the gamma circuit are in different rows in the non-display area, the gamma circuit and the data output circuit are connected with each other by the first connection line, and the first connection line at least partially overlaps the data processing circuit.

Alternatively or additionally according to some example embodiments, there is provided an electronic device including a display device configured to provide at least one image a display screen. The display device comprises a display panel comprising a display area and a non-display area, a data driver in the non-display area of the display panel and connected to a data line in the display area, a gamma circuit in the non-display area of the display panel and connected to the data driver, and a first connection line connecting the gamma circuit with the data driver. The data driver comprises a data processing circuit, and a data output circuit connected to the data processing circuit and the data line, the data output circuit and the gamma circuit are arranged in different rows in the non-display area, the gamma circuit and the data output circuit are connected with each other by the first connection line, and the first connection line at least partly overlaps the data processing circuit.

According to some example embodiments, a data output circuit can be formed on a high-resolution display panel of a display device without reducing a channel width, and/or circuits spaced apart from each other can be easily connected with each other.

The effects of example embodiments are not limited to the above-described effects and other effects which are not described herein will become apparent to those of ordinary skill in the art from the following description.

### BRIEF DESCRIPTION OF THE DRAWINGS

The above and other aspects and features of the present disclosure will become more apparent by describing in detail some example embodiments thereof with reference to the attached drawings, in which:

FIG. 1 is an exploded, perspective view of a display device according to some example embodiments.

FIG. 2 is a block diagram showing a display device according to some example embodiments of the present disclosure.

FIG. 3 is an equivalent circuit diagram of a first sub-pixel according to some example embodiments.

FIG. 4 is a view showing an example of a layout of a display panel according to some example embodiments.

FIGS. 5 and 6 are views showing examples of the layout of the display area of FIG. 4.

FIG. 7 is a cross-sectional view showing an example of the display panel taken along line I1-I1′ of FIG. 5.

FIG. 8 is a cross-sectional view showing area A1 of FIG. 7 in detail.

FIG. 9 is a view showing a layout of a display panel according to some example embodiments.

FIG. 10 is a block diagram of the data driver of FIG. 9.

FIG. 11 is a view for illustrating the positions of a data processing circuit, a data output circuit and a gamma circuit of a display device according to an embodiment.

FIG. 12 is a view for illustrating the positions of a data processing circuit, a data output circuit and a gamma circuit of a display device according to another embodiment.

FIG. 13 is a block diagram of an electronic device according to some example embodiments.

FIGS. 14, 15 and 16 are views showing electronic devices according to a variety of embodiments of the present disclosure.

### DETAILED DESCRIPTION OF EXAMPLE EMBODIMENTS

Some example embodiments will now be described more fully hereinafter with reference to the accompanying drawings, in which some example embodiments of inventive concepts are shown. Inventive concepts may, however, be embodied in different forms and should not be construed as limited to example embodiments set forth herein. Rather, these example embodiments are provided so that this disclosure will be thorough and complete, and will fully convey the scope of the invention to those of ordinary skill in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various example embodiments of the present disclosure may be combined partially or totally. As will be clearly appreciated by those skilled in the art, technically various interactions and operations are possible. Various embodiments can be practiced individually or in combination.

Hereinafter, specific example embodiments will be described with reference to the accompanying drawings.

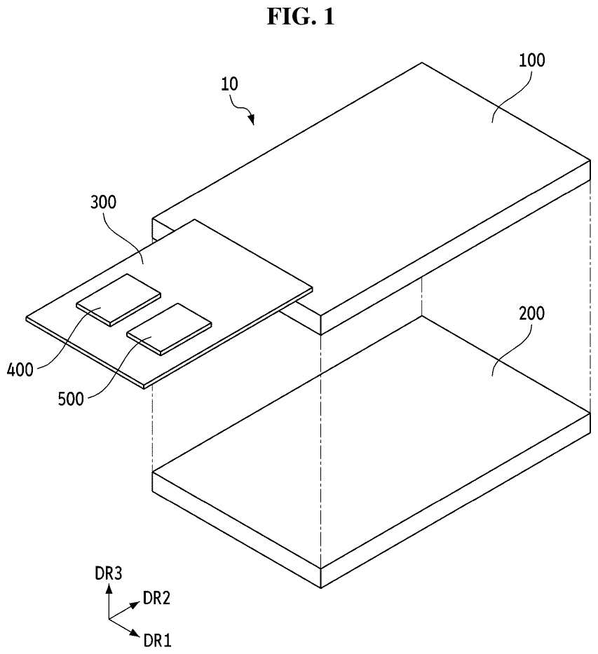

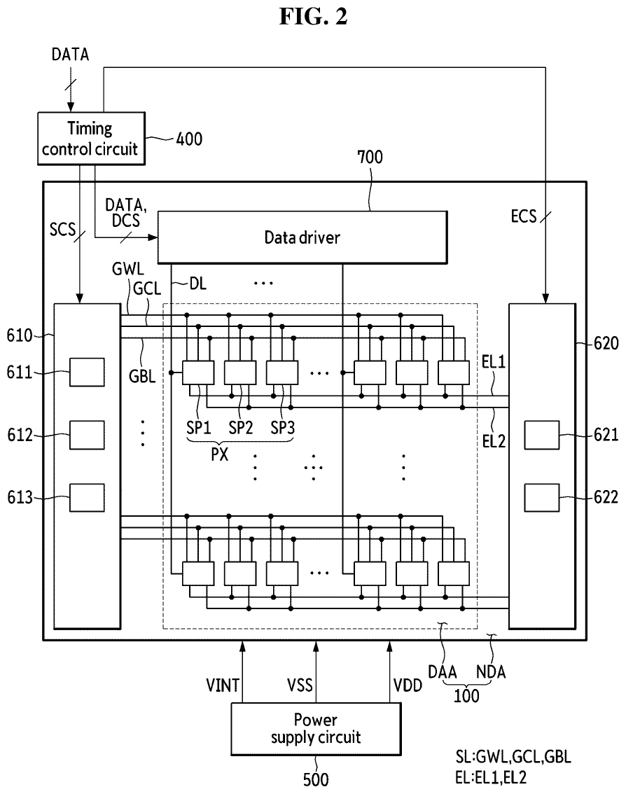

FIG. 1 is an exploded, perspective view of a display device according to some example embodiments. FIG. 2 is a block diagram showing a display device according to some example embodiments of the present disclosure.

Referring to FIGS. 1 and 2, the display device 10 according to some example embodiments displays a moving image or a still image. The display device 10 according to some example embodiments may be employed by portable electronic devices such as one or more of a mobile phone, a smart phone, a tablet PC, a mobile communications terminal, an electronic notebook, an electronic book, a portable multimedia player (PMP), a navigation device or an ultra-mobile PC (UMPC). For example, the display device 10 according to some example embodiments may be used as one or more of a display unit of a television, a laptop computer, a monitor, an electronic billboard, or the Internet of Things (IOT). Alternatively or additionally, the display device 10 according to some example embodiments may be applied to one or more of a smart watch, a watch phone, or a head-mounted display (HMD) for implementing virtual reality and augmented reality.

According to some example embodiments, the display device 10 includes a display panel 100, a heat dissipation layer 200, a circuit board 300, a timing control circuit 400, and a power supply circuit 500.

The display panel 100 may have a shape similarly to a rectangular shape when viewed from the top or from a plan view. For example, the display panel 100 may have a shape similar to a rectangle having shorter sides in the first direction DR1 and longer sides in the second direction DR2 intersecting the first direction DR1 when viewed from the top. In the display panel 100, al or at least one of the corners where the shorter sides in the first direction DR1 meet the longer sides in the second direction DR2 may be rounded with a curvature, such as but not limited to a predetermined curvature and/or bevel and/or chamfer, and/or may be a right angle. The shape of the display panel 100 when viewed from the top is not limited to a rectangular shape, but may be formed in a shape similar to other polygonal shapes, a circular shape, or an elliptical shape. The shape of the display device 10 may follow the shape of the display panel 100 when viewed from the top, but some example embodiments are not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA where images are displayed, and a non-display area NDA where no image is displayed as shown in FIG. 2.

The plurality of pixels PX may be located in or at least partly in the display area DAA. The pixels PX may be arranged in a matrix in the first direction DR1 and the second direction DR2. The scan lines SL and the emission control lines EL may extend in the first direction DR1 and may be arranged in the second direction DR2. The data lines DL may extend in the second direction DR2 and may be arranged in the first direction DR1.

The plurality of scan lines SL includes a plurality of write scan lines GWL, a plurality of control scan lines GCL, and a plurality of bias scan lines GBL. The plurality of emission control lines EL includes a plurality of first emission control lines EL1 and a plurality of second emission control lines EL2.

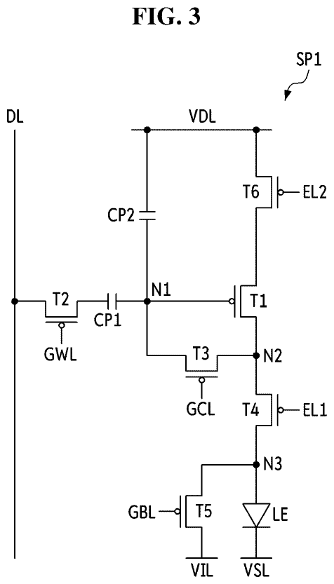

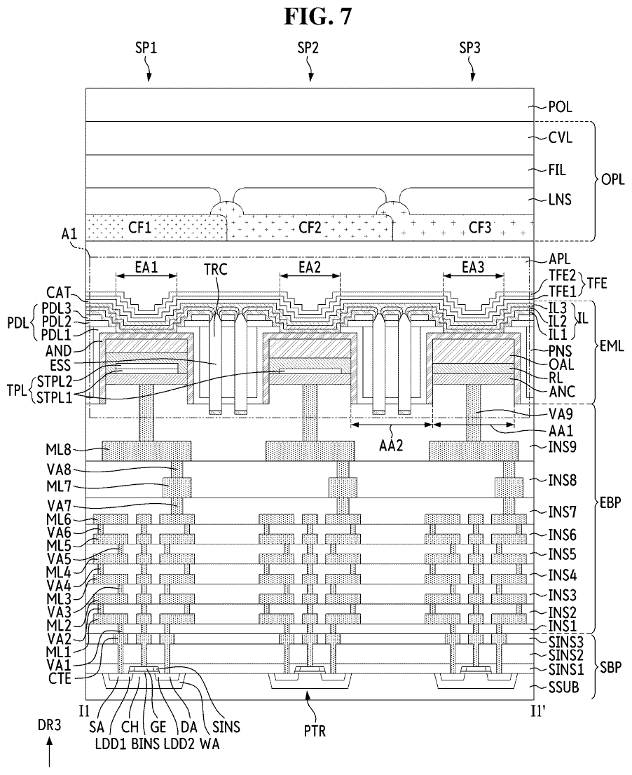

The plurality of pixels PX includes a plurality of sub-pixels SP1, SP2, and SP3; the number of sub-pixels is not necessarily limited to three. The plurality of sub-pixels SP1, SP2 and SP3 includes a plurality of pixel transistors as shown in FIG. 3. The pixel transistors are formed using a semiconductor process and may be located on and/or in a semiconductor substrate SSUB (see FIG. 7). For example, the pixel transistors may be implemented as complementary metal oxide semiconductor (CMOS). It should be understood, however, that example embodiments are not limited thereto.

Each of the sub-pixels SP1, SP2, and SP3 may be connected to one of the write scan lines GWL, one of the control scan lines GCL, one of the bias scan lines GBL, one of the first emission control lines EL1, one of the second emission control lines EL2, and one of the data lines DL. Each of the sub-pixels SP1, SP2, and SP3 may receive the data voltage from the data line DL according to the write scan signal from the write scan line GWL, and may allow the light-emitting elements to emit light according to the data voltage, e.g. emit light of a particular frequency.

The scan driver 610, the emission driver 620, and the data driver 700 may be located in the non-display area NDA.

The scan driver 610 includes a plurality of scan transistors, and the emission driver 620 includes a plurality of light-emitting transistors. A plurality of scan transistors and a plurality of light-emitting transistors are formed using a semiconductor process and may be formed on or at least partly on the semiconductor substrate SSUB (see FIG. 7). For example, a plurality of scan transistors and a plurality of light-emitting transistors may be formed of CMOS. It should be understood, however, that example embodiments are not limited thereto.

The scan driver 610 may include a write scan signal output unit 611, a control scan signal output unit 612, and a bias scan signal output unit 613. A size of and/or a shape of each of the write scan signal output unit 611, the control scan signal output unit 612, and the bias scan signal output unit 613 may be the same as, or different from, each other. Each of the write scan signal output unit 611, the control scan signal output unit 612 and the bias scan signal output unit 613 may receive a scan timing control signal SCS from a timing control circuit 400. The write scan signal output unit 611 may generate write scan signals according to the scan timing control signal SCS from the timing control circuit 400 and sequentially output them to the write scan lines GWL. The control scan signal output unit 612 may generate control scan signals according to the scan timing control signal SCS and sequentially output them to the control scan lines GCL. The bias scan signal output unit 613 may generate bias scan signals according to the scan timing control signal SCS and sequentially output them to the bias scan lines EBL.

The emission driver 620 includes a first emission control driver 621 and a second emission control driver 622. The first emission control driver 621 may have the same size and/or shape as the second emission control driver 622; however, example embodiments are not limited thereto. Each of the first emission control driver 621 and the second emission control driver 622 may receive an emission timing control signal ECS from the timing control circuit 400. The first emission control driver 621 may generate first emission control signals according to the emission timing control signal ECS and may sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed via a semiconductor process and may be formed on the semiconductor substrate SSUB (see FIG. 7). For example, a plurality of data transistors may be formed of CMOS transistors. It should be understood, however, that some example embodiments are not limited thereto.

The data driver 700 may receive digital video data DATA and a data timing control signal DCS from the timing control circuit 400. The data driver 700 converts the digital video data DATA into analog data voltages according to the data timing control signal DCS and outputs them to the data lines DL. In doing so, the sub-pixels SP1, SP2, and SP3 are selected by the write scan signal of the scan driver 610, and data voltages may be applied to the selected sub-pixels SP1, SP2, and SP3.

The heat dissipation layer 200 may overlap with, or at least partly overlap with, \ the display panel 100 in the third direction DR3, which is the thickness direction of the display panel 100. The heat dissipation layer 200 may be located on one surface of the display panel 100, e.g., on the rear surface. The heat dissipation layer 200 serves to release heat generated in the display panel 100. The heat dissipation layer 200 may include a metal layer such as at least one of graphite, silver (Ag), copper (Cu) and aluminum (Al) having a high thermal conductivity.

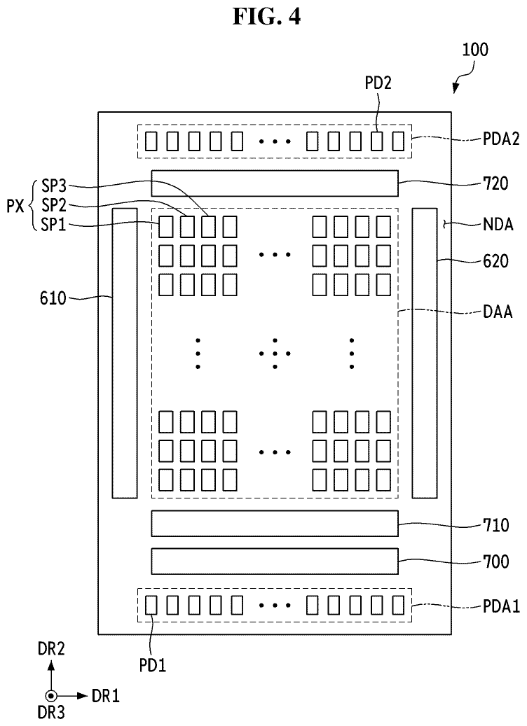

The circuit board 300 may be electrically connected to a plurality of first pads PD1 (see FIG. 4) of a first pad area PDA1 (see FIG. 4) of the display panel 100 using a conductive adhesive member such as an anisotropic conductive film. The circuit board 300 may be or may include a flexible printed circuit board made of a flexible material, or a flexible film. Although the circuit board 300 is unfolded in the example shown in FIG. 1, the circuit board 300 may be bent. When the circuit board 300 is bent, one end of the circuit board 300 may be located on the rear surface of the display panel 100 and/or the rear surface of the heat dissipation layer 200. The other end of the circuit board 300 may be connected to a plurality of first pads PD1 (see FIG. 4) of the first pad area PDA1 (see FIG. 4) of the display panel 100 using a conductive adhesive material. One end of the circuit board 300 may be opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 in response to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

A power supply circuit 500 may generate a plurality of panel driving voltages in response to a supply voltage from the outside. For example, the power supply circuit 500 may generate a first supply voltage VSS (e.g., a ground voltage), a second supply voltage VDD, and a third supply voltage VINT to apply them to the display panel 100. The first supply voltage VSS, the second supply voltage VDD, and the third supply voltage VINT will be described later with reference to FIG. 3.

Each of the timing control circuit 400 and the power supply circuit 500 may be implemented, e.g., implemented separately or concurrently as an integrated circuit (IC) and attached to a surface of the circuit board 300. The scan timing control signal SCS, the emission timing control signal ECS, the digital video data DATA and the data timing control signal DCS from the timing control circuit 400 may be supplied to the display panel 100 through the circuit board 300. The first supply voltage VSS, the second supply voltage VDD, and the third supply voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620 and the data driver 700. In this instance, the timing control circuit 400 may include a plurality of timing transistors, and each power supply circuit 500 may include a plurality of power transistors. A plurality of timing transistors and a plurality of power transistors may be formed via a semiconductor process and may be formed on the semiconductor substrate SSUB (see FIG. 7). For example, the plurality of timing transistors and the plurality of power transistors may be formed of CMOS transistors. It should be understood, however, that some example embodiments are not limited thereto. Each of the timing control circuit 400 and the power supply circuit 500 may be located between the data driver 700 and the first pad area PDA1 (see FIG. 4).

FIG. 3 is an equivalent circuit diagram of a first sub-pixel according to some example embodiments.

Referring to FIG. 3, a first sub-pixel SP1 may be connected to a write scan line GWL, a control scan line GCL, a bias scan line EBL, a first emission control line EL1, a second emission control line EL2, and a data line DL. In some example embodiments, the first sub-pixel SP1 may be connected to a first supply voltage line VSL where the first supply voltage VSS equal to a low-level voltage is applied, a second supply voltage line VDL where the second supply voltage VDD equal to a high-level voltage is applied, and a third supply voltage line VIL where the third supply voltage VINT equal to an initialization voltage is applied. For example, the first supply voltage line VSL may be a low-level voltage line, the second supply voltage line VDL may be a high-level voltage line, and the third supply voltage line VIL may be an initialization voltage line. The first supply voltage VSS may be lower than (e.g., lower in absolute value than) the third supply voltage VINT. The second supply voltage VDD may be higher than (e.g., higher in absolute value than) the third supply voltage VINT.

The first sub-pixel SP1 includes a plurality of transistors T1 to T6, a light-emitting element LE, a first capacitor CP1, and a second capacitor CP2.

The light-emitting element LE emits light according to a driving current Ids flowing in a channel of the first transistor T1. The amount of the light emitted from the light-emitting element LE may be proportional to the driving current Ids. The light-emitting element LE may be located between the fourth transistor T4 and the first supply voltage line VSL. The first electrode of the light-emitting element LE may be connected to a drain electrode of the fourth transistor T4, and the second electrode thereof may be connected to the first supply voltage line VSL. The first electrode of the light-emitting element LE may be an anode electrode, and the second electrode of the light-emitting element LE may be a cathode electrode. The light-emitting element LE may be or may include an organic light-emitting diode including a first electrode, a second electrode, and an organic light-emitting layer located between the first electrode and the second electrode. It should be understood, however, that the present disclosure is not limited thereto. For example, the light-emitting element LE may be or may include an inorganic light-emitting element including a first electrode, a second electrode, and an inorganic semiconductor located between the first electrode and the second electrode. In this instance, the light-emitting element LE may be or may include a micro light-emitting diode.

The first transistor T1 may be a driving transistor for controlling the source-drain current Ids (hereinafter referred to as “driving current”) flowing between the source electrode and the drain electrode according to the voltage applied to the gate electrode. The first transistor T1 includes a gate electrode connected to a first node N1, a source electrode connected to a drain electrode of the sixth transistor T6, and a drain electrode connected to a second node N2.

The second transistor T2 may be located between one electrode of the first capacitor CP1 and the data line DL. The second transistor T2 is turned on by a write scan signal from the write scan line GWL and connects the electrode of the first capacitor CP1 to the data line DL. Accordingly, the data voltage of the data line DL may be applied to the electrode of the first capacitor CP1. The second transistor T2 includes a gate electrode connected to the write scan line GWL, a source electrode connected to the data line DL, and a drain electrode connected to the electrode of the first capacitor CP1.

A third transistor T3 may be located between the first node N1 and the second node N2. The third transistor T3 is turned on by the write control signal of the write control line GCL and connects the first node N1 to the second node N2. Accordingly, if the gate electrode and source electrode of the first transistor T1 are connected with each other, the first transistor T1 may act like a diode. The third transistor T3 includes a gate electrode connected to the write control line GCL, a source electrode connected to the second node N2, and a drain electrode connected to the first node N1.

The fourth transistor T4 may be connected between the second node N2 and the third node N3. The fourth transistor T4 is turned on by a first emission control signal of the first emission control line EL1 and connects the second node N2 to the third node N3. Accordingly, the driving current of the first transistor T1 may be supplied to the light-emitting element LE. The fourth transistor T4 includes a gate electrode connected to the first emission control line EL1, a source electrode connected to the second node N2, and a drain electrode connected to the third node N3.

The fifth transistor T5 may be located between the third node N3 and the third supply voltage line VIL. The fifth transistor T5 is turned on by a bias scan signal of the bias scan line EBL and connects the third node N3 to the third supply voltage line VIL. Accordingly, the third supply voltage VINT of the third supply voltage line VIL may be applied to the first electrode of the light-emitting element LE. The fifth transistor T5 includes a gate electrode connected to the bias scan line EBL, a source electrode connected to the third node N3, and a drain electrode connected to the third driving voltage line VIL.

The sixth transistor T6 may be located between the source electrode of the first transistor T1 and the second supply voltage line VDL. The sixth transistor T6 is turned on by the second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes a first electrode connected to the drain electrode of the second transistor T2, and a second electrode connected to the first node N1.

The second capacitor CP2 is formed between the gate electrode of the driving transistor DT and the second driving voltage line VDL. The second capacitor CP2 includes a first electrode connected to the gate electrode of the first transistor T1 and a second electrode connected to the second driving voltage line VDL.

The first node N1 is a contact point where the gate electrode of the first transistor T1, the drain electrode of the third transistor T3, the second electrode of the first capacitor CP1 and the first electrode of the second capacitor CP2 meet. The second node N2 is a contact point where the drain electrode of the first transistor T1, the source electrode of the third transistor T3 and the source electrode of the fourth transistor T4 meet. The third node N3 is a contact point where the drain electrode of the fourth transistor T4, the source electrode of the fifth transistor T5, and the first electrode of the light-emitting element LE meet.

Each of the first to sixth transistors T1 to T6 may be or may include a metal-oxide-semiconductor field effect transistor (MOSFET). For example, each of the first to sixth transistors T1 to T6 may be, but is not limited to, a p-type MOSFET. Each of the first to sixth transistors T1 to T6 may be an n-type MOSFET. Alternatively, some of the first to sixth transistors T1 to T6 may be p-type MOSFETs, and the other transistors may be n-type MOSFETs. Electrical and/or physical properties, such as gate widths and/or gate lengths and/or threshold voltages of each of the first to sixth transistors T1 to T6 may be the same as each other; however, example embodiments are not limited thereto. Alternatively or additionally, electrical and/or physical properties of each of the first to sixth transistors T1 to T6 may be different from each other; example embodiments are not limited thereto. Alternatively or additionally, electrical and/or physical properties of the first capacitor CP1 and the second capacitor CP2 may be the same as each other; example embodiments are not limited thereto.

Although the first sub-pixel SP1 includes the six transistors T1 to T6 and the two capacitors C1 and C2 in the example shown in FIG. 3, it should be noted that the equivalent circuit diagram of the first sub-pixel SP1 is not limited to that shown in FIG. 3. For example, the numbers of the transistors and/or the capacitors of the first sub-pixel SP1 are not limited to those shown in FIG. 3.

In addition, the equivalent circuit diagram of the second sub-pixel SP2 and the equivalent circuit diagram of the third sub-pixel SP3 may be substantially identical to the equivalent circuit diagram of the first sub-pixel SP1 described above with reference to FIG. 3; and, therefore, the redundant descriptions will be omitted.

FIG. 4 is a view showing an example of a layout of a display panel according to some example embodiments.

Referring to FIG. 4, the display area DAA of the display panel 100 according to some example embodiments includes a plurality of pixels PX arranged in a matrix. The non-display area NDA of the display panel 100 according to some example embodiments includes the scan driver 610, the emission driver 620, the data driver 700, a first distribution circuit 710, a second distribution circuit 720, a first pad area PDA1, and a second pad area PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the opposite side of the display area DAA in the first direction DR1. Specifically, the scan driver 610 may be located on one side (e.g., the left side_ of the display area DAA, and the emission driver 620 may be located on another side (e.g., the right side) of the display area DAA. It should be understood, however, that some example embodiments are not limited thereto. The scan driver 610 and the emission driver 620 may be located on both the first and second sides of the display area DAA.

The first pad area PDA1 may include a plurality of first pads PD1 connected to pads or bumps of the circuit board 300 through a conductive adhesive member. The first pad area PDA1 may be located on a third side of the display area DAA. For example, the first pad area PDA1 may be located on one side of the display area DAA in the second direction DR2. The first pad area PDA1 may be located on the outer side of the data driver 700 in the second direction DR2. For example, the first pad area PDA1 may be located closer to the edge of the display panel 100 than the data driver 700 is.

The second pad area PDA2 may include a plurality of second pads PD2 which is test pads for testing whether the display panel 100 operates normally. The plurality of second pads PD2 may be connected to a jig or a probe pin during a test process, or may be connected to a circuit board for testing. The circuit board for testing may be a printed circuit board made of a rigid material or a flexible printed circuit board made of a flexible material.

The second pad area PDA2 may be located on a fourth side of the display area DAA. For example, the second pad area PDA2 may be located on the opposite side of the display area DAA in the second direction DR2. The second pad area PDA2 may be located on the outer side of the second distribution circuit 700 in the second direction DR2. For example, the second pad area PDA2 may be located closer to the edge of the display panel 100 than the second distribution circuit 720.

The first distribution circuit 710 distributes data voltages applied via the first pad area PDA1 to a plurality of data lines DL. For example, the first distribution circuit 710 may divide the data voltages applied via one first pad PD1 of the first pad area PDA1 into P data lines DL, thereby reducing the number of the plurality of first pads PD1, where P is a positive integer equal to or greater than two. The first distribution circuit 710 may be located on the third side of the display area DAA of the display panel 100. For example, the first distribution circuit 710 may be located on one side of the display area DAA in the second direction DR2. For example, the first distribution circuit 710 may be located on the lower side of the display area DAA.

The second distribution circuit 720 distributes signals applied through the second pad area PDA2 to the scan driver 610, the emission driver 620, and the data lines DL. The second pad area PDA2 and the second distribution circuit 720 may be elements to test the operation of each of the pixels PX in the display area DAA. The second distribution circuit 720 may be located on a fourth side of the display area DAA of the display panel 100. For example, the second distribution circuit 720 may be located on the opposite side of the display area DAA in the second direction DR2. For example, the second distribution circuit 720 may be located on the upper side of the display area DAA.

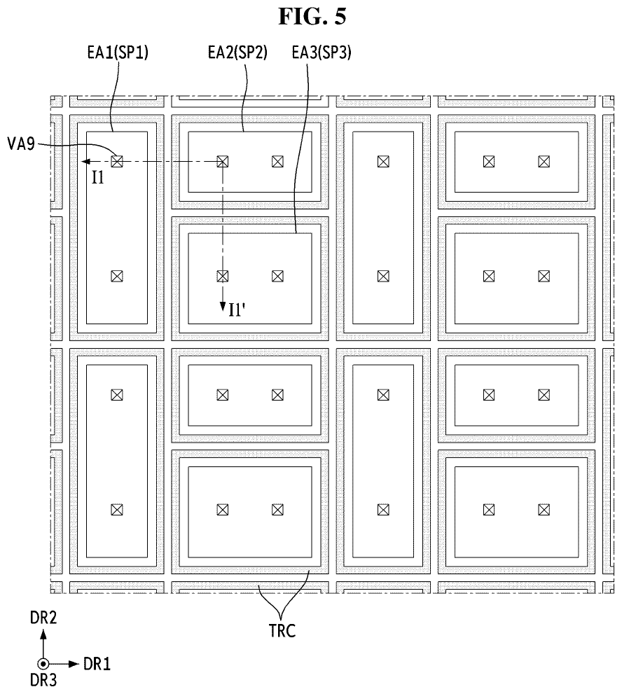

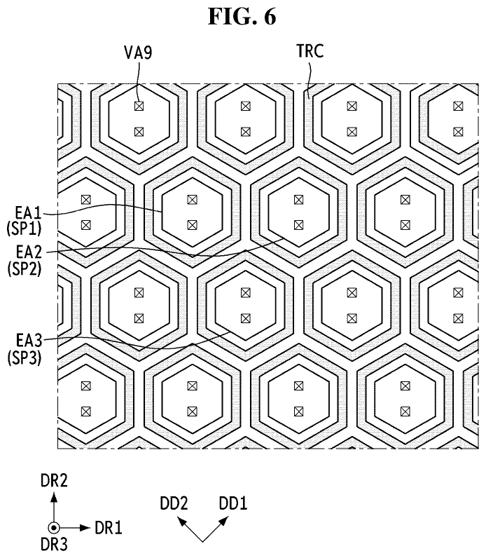

FIGS. 5 and 6 are views showing examples of the layout of the display area of FIG. 4.

Referring to FIGS. 5 and 6, each of the plurality of pixels PX includes a first emission area EA1 that is the emission area of the first sub-pixel SP1, a second emission area EA2 that is the emission area of the second sub-pixel SP2, and a third emission area EA3 that is the emission area of the third sub-pixel SP3.

Each of the first emission area EA1, the second emission area EA2, and the third emission area EA3 may independently have a polygonal shape, a circular shape, an elliptical shape, and/or an irregular shape when viewed from the top.

Referring to FGI. 5, the maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 may be substantially equal to the maximum length of the third emission area EA3 in the first direction DR1.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

Referring to FIG. 6, in some example embodiments, the first emission area EA1, the second emission area EA2 and the third emission area EA3 may have a hexagonal shape consisting of (or including) six straight lines when viewed from the top. It should be understood, however, that some example embodiments are not limited thereto. The first emission area EA1, the second emission area EA2 and the third emission area EA3 may have a polygonal shape other than a hexagon, a circular shape, an elliptical shape or an irregular shape when viewed from the top.

As shown in FIG. 5, in each of the plurality of pixels PX, the first emission area EA1 and the second emission area EA2 may be adjacent to each other in the first direction DR1. In addition, the first emission area EA1 and the third emission area EA3 may be adjacent to each other in the first direction DR1. In addition, the second emission area EA2 and the third emission area EA3 may be adjacent to each other in the first direction DR1. The first emission area EA1, the second emission area EA2 and the third emission area EA3 may have different areas.

Alternatively, as shown in FIG. 6, the first emission area EA1 and the second emission area EA2 may be adjacent to each other in the first direction DR1, the second emission area EA2 and the third emission area EA3 may be adjacent to each other in a first diagonal direction DD1, and the first emission area EA1 and the third emission area EA3 may be adjacent to each other in a second diagonal direction DD2. The first diagonal direction DD1 refer to a direction between the first direction DR1 and the second direction DR2, and refers to a direction inclined by 45 degrees relative to the first direction DR1 and the second direction DR2. The second diagonal direction DD2 may be orthogonal to the first diagonal direction DD1.

The first sub-pixel SP1 may output the first light that has passed through a first color filter CF1 (see FIG. 7) from among the lights output from the first emission area EA1, the second sub-pixel SP2 may output the second light that has passed through a second color filter CF2 (see FIG. 7) from among the lights output from the second emission area EA2, and the third sub-pixel SP3 may output the third light that has passed through a third color filter CF3 (see FIG. 7) from among the lights output from the third emission area EA3. One of the first to third lights may be light in the blue wavelength range, another light may be light in the green wavelength range, and the other light may be light in the red wavelength range; example embodiments are not limited thereto. For example, the blue wavelength range may refer that the main peak wavelength of light lies in the wavelength range of approximately 370 nm to 460 nm, the green wavelength range may refer that the main peak wavelength of light lies in the wavelength range of approximately 480 nm to 560 nm, and the red wavelength range may refer to that the main peak wavelength of light lies in the wavelength range of approximately 600 nm to 750 nm.

Although each of the plurality of pixels PX includes three emission areas EA1, EA2 and EA3 in the example shown in FIGS. 5 and 6, example embodiments are not limited thereto. For example, each of the plurality of pixels PX may include four emission areas.

Alternatively or additionally, the layout of the emission areas of the plurality of pixels PX is not limited to that shown in FIGS. 5 and 6. For example, the emission areas of the plurality of pixels PX may have a stripe structure in which the emission areas are arranged in the first direction DR1, a PenTile® matrix in which the emission areas have a diamond arrangement, and/or a hexagonal structure in which emission areas having a hexagonal shape when viewed from the top are arranged as shown in FIG. 6.

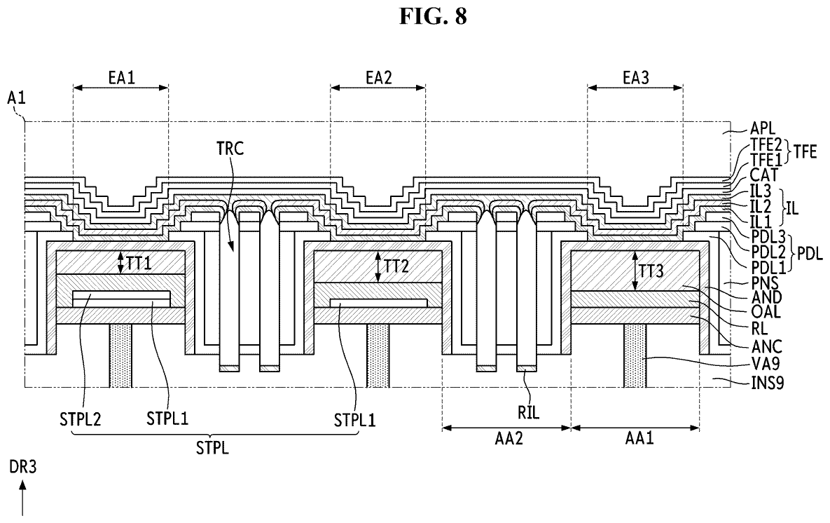

FIG. 7 is a cross-sectional view showing an example of the display panel taken along line I1-I1′ of FIG. 5. FIG. 8 is a cross-sectional view showing area A1 of FIG. 7 in detail.

Referring to FIGS. 7 and 8, the display panel 100 includes a semiconductor backplane SBP, a light-emitting element backplane EBP, a display element layer EML, an encapsulation layer TFE, an optical layer OPL, a cover layer CVL, and a polarizer POL.

The semiconductor backplane SBP includes a semiconductor substrate SSUB including a plurality of pixel transistors PTR (e.g., planar transistors), a plurality of semiconductor insulating films covering the plurality of pixel transistors PTR, and a plurality of contact terminals CTE that are electrically connected to the pixel transistors PTR, respectively. The plurality of pixel transistors PTR may be or may correspond to the first to sixth transistors T1 to T6 described above with reference to FIG. 4.

The semiconductor substrate SSUB may be or include a silicon substrate, a germanium substrate, or a silicon-germanium substrate. The semiconductor substrate SSUB may be or include a substrate doped with first-type impurities. A plurality of well areas WA may be arranged in the upper surface of the semiconductor substrate SSUB. The well areas WA may be doped with second-type impurities. The second-type impurities may be different from the first-type impurities. For example, when the first-type impurities are p-type impurities such as but not limited to boron, the second-type impurities may be n-type impurities such as but not limited to phosphorus and/or arsenic. Alternatively, when the first-type impurities are n-type impurities, the second-type impurities may be p-type impurities.

Each of the well areas WA includes a source region SA associated with a source electrode of a pixel transistor PTR, a drain region DA associated with a drain electrode thereof, and a channel region CH between the source region SA and the drain region DA.

A bottom insulating film BINS may be located between the gate electrode GE and the well areas WA. Side insulating films SINS may be located on the side surfaces of the gate electrode GE. The side insulating films SINS may be located on the bottom insulating film BINS.

Each of the source region SA and the drain region DA may be doped with the first-type impurities. The gate electrode GE of the pixel transistor PTR may overlap with the well area WA in the third direction DR3 which is the thickness direction of the semiconductor substrate SSUB. The channel region CH may overlap with the gate electrode GE in the third direction DR3. The source area SA may be located on one side of the gate electrode GE, and the drain area SA may be located on the opposite side of the gate electrode GE.

Each of the plurality of well areas WA may further include a first low-concentration impurity region LDD1, or first lightly-doped drain region, located between the channel region CH and the source region SA, and a second low-concentration impurity region LDD2, or second lightly-doped drain region, located between the channel region CH and the drain region DA. The first low-concentration impurity region LDD1 may have a lower impurity concentration than the source region SA due to the bottom insulating film BINS. The second low-concentration impurity region LDD2 may have a lower impurity concentration than the drain region SA due to the bottom insulating film BINS. The distance between the source region SA and the drain region DA may be increased by the first low-concentration impurity region LDD1 and the second low-concentration impurity region LDD2. Therefore, the length of the channel region CH of each of the pixel transistors PTR can be increased, and thus it is possible to prevent or reduce the likelihood of and/or the impact from punch-through and/or hot carrier phenomenon due to short channel.

A first semiconductor insulating film SINS1 may be located on the semiconductor substrate SSUB. The first semiconductor insulating film SINS1 may be formed of, but is not limited to, a silicon carbon nitride (SiCN) and/or a silicon oxide (SiOx)-based inorganic film.

A second semiconductor insulating film SINS2 may be located on the first semiconductor insulating film SINS1. The second semiconductor insulating film SINS2 may be formed of a silicon oxide (SiOx)-based inorganic film, but example embodiments are not limited thereto.

A plurality of contact terminals CTE may be located on the second semiconductor insulating film SINS2. Each of the plurality of contact terminals CTE may be connected to one of the gate electrode GE, the region SA and the drain region DA of each of the pixel transistors PTR through a hole penetrating the first semiconductor insulating film SINS1 and the second semiconductor insulating layer INS2. The contact terminals CTE may be made of one or more than one of copper (Cu), aluminum (Al), tungsten (W), molybdenum (Mo), chromium (Cr), gold (Au), titanium (Ti), nickel (Ni) and neodymium (Nd), or an alloy containing one of these.

A third semiconductor insulating film SINS3 may be located on the side surface of each of the contact terminals CTE. The upper surface of each of the contact terminals CTE may not be covered by the third semiconductor insulating film SINS3 but may be exposed. The third semiconductor insulating film SINS3 may be formed of a silicon oxide (SiOx)-based inorganic film, but example embodiments are not limited thereto.

The semiconductor substrate SSUB may be replaced with and/or included with a glass substrate and/or a polymer resin substrate such as polyimide. In this instance, thin-film transistors may be arranged on a glass substrate or a polymer resin substrate. The glass substrate may be a rigid substrate that is not bent, while the polymer resin substrate may be a flexible substrate that can be bent or curved.

The light-emitting element backplane EBP includes a plurality of conductive layers ML1 to ML8, a plurality of via electrodes VA1 to VA9, and a plurality of insulating films INS1 to INS11. In addition, the light-emitting element backplane EBP includes a plurality of insulating films INS1 to INS11 arranged between the first to eighth conductive layers ML1 to ML8. A thickness of and/or a composition of each of the plurality of insulating films INS1 to INS11 may be the same; alternatively, a thickness of and/or a composition of at least one of the plurality of insulating films INS1 to INS11 may be different than others. Additionally or alternatively, a thickness of and/or a composition of and/or a line-width of each of the first to eight conductive layers ML1 to ML8 may be the same; alternatively, at least one of a thickness of, a composition of, or a line-width of at least one of the first to eight conductive layers ML1 to ML8 may be different than others.

The first to eighth conductive layers ML1 to ML8 may implement a circuit of a first sub-pixel SP1 shown in FIG. 4 by connecting a plurality of contact terminals CTE exposed from the semiconductor backplane SBP. For example, the first to sixth transistors T1 to T6 are only formed in the semiconductor backplane SBP, and the connection of the first to sixth transistors T1 to T6 and the first capacitor C1 and the second capacitor C2 are made through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE is also made through the first to eighth conductive layers ML1 to ML8.

The first insulating layer INS1 may be located on the semiconductor backplane SBP. Each of the first via electrodes VA1 may penetrate the first insulating layer INS1 and may be connected to the contact terminal CTE exposed from the semiconductor backplane SBP. Each of the first conductive layers ML1 may be arranged on the first insulating layer INS1 and may be connected to the first via electrode VA1.

The second insulating layer INS2 may be located on the first insulating layer INS1 and the first conductive layers ML1. Each of the second via electrodes VA2 may penetrate through the second insulating layer INS2 to be connected to the exposed first metal layer ML1. Each of the second conductive layers ML2 may be located on the second insulating layer INS2 and may be connected to the second via electrode VA2.

The third insulating layer INS3 may be located over the second insulating layer INS2 and the second conductive layers ML2. Each of the third via electrodes VA3 may penetrate through the third insulating layer INS3 to be connected to the exposed second conductive layer ML2. Each of the third conductive layers ML3 may be located on the third insulating layer INS3 and may be connected to the third via electrode VA3.

The fourth insulating layer INS4 may be located over the third insulating layer INS3 and the third conductive layers ML3. Each of the fourth via electrodes VA4 may penetrate through the fourth insulating layer INS4 to be connected to the exposed third conductive layer ML3. Each of the fourth conductive layers ML4 may be located on the fourth insulating layer INS4 and may be connected to the fourth via electrode VA4.

The fifth insulating layer INS5 may be located over the fourth insulating layer INS4 and the fourth conductive layers ML4. Each of the fifth via electrodes VA5 may penetrate through the fifth insulating layer INS5 to be connected to the exposed fourth conductive layer ML4. Each of the fifth conductive layers ML5 may be located on the fifth insulating layer INS5 and may be connected to the fifth via electrode VA5.

The sixth insulating layer INS6 may be located over the fifth insulating layer INS5 and the fifth conductive layers ML5. Each of the sixth via electrodes VA6 may penetrate through the sixth insulating layer INS6 to be connected to the exposed fifth conductive layer ML5. Each of the sixth conductive layers ML6 may be located on the sixth insulating layer INS6 and may be connected to the sixth via electrode VA6.

The seventh insulating layer INS7 may be located over the sixth insulating layer INS6 and the sixth conductive layers ML6. Each of the seventh via electrodes VA7 may penetrate through the seventh insulating layer INS7 to be connected to the exposed sixth conductive layer ML6. Each of the seventh conductive layers ML7 may be located on the seventh insulating layer INS7 and may be connected to the seventh via electrode VA7.

The eighth insulating layer INS8 may be located over the seventh insulating layer INS7 and the seventh conductive layers ML7. Each of the eighth via electrodes VA8 may penetrate through the eighth insulating layer INS8 to be connected to the exposed seventh conductive layer ML7. Each of the eighth conductive layers ML8 may be located on the eighth insulating layer INS8 and may be connected to the eighth via electrode VA8.

The first to eighth conductive layers ML1 to ML8 and the first to eighth via electrodes VA1 to VA8 may be made of substantially the same material; example embodiments are not limited thereto. The first to eighth conductive layers ML1 to ML8 and the first to eighth via elements VA1 to VA8 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. The first to eighth via electrodes VA1 to VA8 may be made of substantially the same material. The first to eighth insulating films INS1 to ILD8 may be formed as inorganic films such as silicon oxide films, but embodiments of the present specification are not limited thereto. The first to eight conductive layers ML1 to ML8 and the first to eight via elements VA1 to VA8 may be formed with a via-first, via-middle, and/or via-last dual-damascene process; example embodiments are not limited thereto.

The thickness of the first conductive layer ML1, the thickness of the second conductive layer ML2, the thickness of the third conductive layer ML3, the thickness of the fourth conductive layer ML4, the thickness of the fifth conductive layer ML5 and the thickness of the sixth conductive layer ML6 may be greater than the thickness of the first via electrode VA1, the thickness of the second via electrode VA2, the thickness of the third via electrode VA3, the thickness of the fourth via electrode VA4, the thickness of the fifth via electrode VA5 and the thickness of the sixth via electrode VA6. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5 and the thickness of the sixth conductive layer ML6 may be substantially all equal. For example, the thickness of the first conductive layer ML1 may be approximately 1,360 Å, the thickness of the second conductive layer ML2, the thickness of the third conductive layer ML3, the thickness of the fourth conductive layer ML4, the thickness of the fifth conductive layer ML5 and the thickness of the sixth conductive layer ML6 may be approximately 1,440 Å, and the thickness of the first via electrode VA1, the thickness of the second via electrode VA2, the thickness of the third via electrode VA3, the thickness of the fourth via electrode VA4, the thickness of the fifth via electrode VA5 and the thickness of the sixth via electrode VA6 may be approximately 1,150 Å.

The thickness of the seventh conductive layer ML7 and the thickness of the eighth conductive layer ML8 may be greater than the thickness of the first conductive layer ML1, the thickness of the second conductive layer ML2, the thickness of the third conductive layer ML3, the thickness of the fourth conductive layer ML4, the thickness of the fifth conductive layer ML5 and the thickness of the sixth conductive layer ML6. The thickness of the seventh conductive layer ML7 and the thickness of the eighth conductive layer ML8 may be greater than the thickness of the seventh via electrode VA7 and the thickness of the eighth via electrode VA8. The thickness of the seventh via electrode VA7 and the thickness of the eighth via electrode VA8 may be greater than the thickness of the first via electrode VA1, the thickness of the second via electrode VA2, the thickness of the third via electrode VA3, and the thickness of the fourth via electrode VA4, the thickness of the fifth via electrode VA5 and the thickness of the sixth via electrode VA6. The thickness of the seventh conductive layer ML7 may be substantially equal to the thickness of the eighth conductive layer ML8. For example, the thickness of the seventh conductive layer ML7 and the thickness of the eighth conductive layer ML8 may be approximately 9,000 Å; example embodiments are not limited thereto. The thickness of the seventh via electrode VA7 and the thickness of the eighth via electrode VA8 may be approximately 6,000 Å; example embodiments are not limited thereto.

The ninth insulating layer INS9 may be located over the eighth insulating layer INS8 and the eighth conductive layer ML8. The ninth insulating layer INS9 may be formed as an inorganic film such as a silicon oxide (SiOx) film, but some example embodiments are not limited thereto.

Each of the ninth via electrodes VA9 may penetrate through the ninth insulating layer INS9 to be connected to the exposed eighth conductive layer ML8. The ninth via electrodes VA9 may be made of one of copper (Cu), aluminum (Al), tungsten (W), molybdenum (Mo), chromium (Cr), gold (Au), titanium (Ti), nickel (Ni) and neodymium (Nd), or an alloy containing one of these. The thickness of the ninth via electrode VA9 may be approximately 16,500 Å.

The display element layer EML may be located on the light-emitting element backplane EBP. The display element layer EML may include a plurality of connection electrodes ANC, a plurality of reflective electrodes RL, a planarization film PNS, a pixel-defining layer PDL, a plurality of first electrodes AND, an emission stack IL, a second electrode CAT, and a plurality of trenches TRC.

Alternatively or additionally, the display element layer EML may include a first emission area EA1, a second emission area EA2, and a third emission area EA3. In each of the first emission area EA1, the second emission area EA2 and the third emission area EA3, the first electrode AND, the emission stack IL and the second electrode CAT may be sequentially stacked on one another. In each of the first emission area EA1, the second emission area EA2 and the third emission area EA3, a light-emitting element LE including a first electrode AND, an emission stack IL, and a second electrode CAT is located. Each of the first emission areas EA1, the second emission areas EA2 and the third emission areas EA3 may be defined by the first pixel-defining layer PDL1.

The ninth insulating layer INS9 may include first areas AA1 in line with the connection electrodes ANC, and second areas AA2 arranged around the first areas AA1. The thickness of the first areas AA1 of the ninth insulating layer INS9 may be greater than the thickness of the second areas AA2 of the ninth insulating layer INS9.

The connection electrodes ANC may be arranged on the first areas AA1 of the ninth insulating layer INS9, respectively. Each of the connection electrodes ANC may be arranged on the respective first areas AA1. Each of the connection electrodes ANC may be made of titanium nitride (TiN) or a transparent conductive oxide. For example, the transparent conductive oxide may be or include, but is not limited to, indium tin oxide (ITO) and/or indium zinc oxide (IZO).

The step layer STPL includes a first step layer STPL1 and a second step layer STPL2. The first step layer STPL1 and the second step layer STPL2 may be formed as, but is not limited to, inorganic films such as a silicon carbon nitride (SiCN) film and/or a silicon oxide (SiOx) film.

The first step layer STPL1 may be located on the connection electrode ANC in each of the first sub-pixels SP1 and the second sub-pixels SP2. In addition, the second step layer STPL2 may be arranged on the first step layer STPL1 in each of the first sub-pixels SP1. No step layer STPL may be disposed in each of the third sub-pixels SP3.

In each of the first sub-pixels SP1, the reflective electrode RL may be disposed on the connection electrode ANC, the first step layer STPL1 and the second step layer STPL2. For example, in each of the first sub-pixels SP1, the reflective electrode RL may cover the upper surface of the connection electrode ANC, the side surfaces of the first step layer STPL1, and the upper surface and side surfaces of the second step layer STPL2.

In each of the second sub-pixels SP2, the reflective electrode RL may be located on the connection electrode ANC and the first step layer STPL1. For example, in each of the second sub-pixels SP2, the reflective electrode RL may cover the upper surface of the connection electrode ANC, and the upper surface and the side surfaces of the first step layer STPL1.

In each of the third sub-pixels SP3, the reflective electrode RL may be located on the connection electrode ANC. For example, in each of the third sub-pixels SP3, the reflective electrode RL may cover the upper surface of the connection electrode ANC.

Each of the reflective electrodes RL may be made of one or more of copper (Cu), aluminum (Al), tungsten (W), molybdenum (Mo), chromium (Cr), gold (Au), titanium (Ti), nickel (Ni) and neodymium (Nd), or an alloy containing at least one of these. For example, each of the reflective electrodes RL may include aluminum (Al) having high reflectivity.

A plurality of optical auxiliary layers OAL may be located on the reflective electrodes RL, respectively. The optical auxiliary layers OAL may be associated with the reflective electrodes RL, respectively. The optical auxiliary layers OAL may be made of an inorganic film such as a silicon oxide (SiOx) film, but some example embodiments are not limited thereto.

Due to the first step layer STPL1 and the second step layer STPL2, the thickness TT1 of the optical auxiliary layer OAL in the first sub-pixel SP1, the thickness TT2 of the optical auxiliary layer OAL in the second sub-pixel SP2, and the thickness TT3 of the optical auxiliary layer OAL in the third sub-pixel SP3 may be different from one another. For example, due to the first step layer STPL1 and the second step layer STPL2, the thickness TT1 of the optical auxiliary layer OAL in the first sub-pixel SP1 may be the smallest. Alternatively or additionally, the thickness TT3 of the optical auxiliary layer OAL may be the largest in the third sub-pixel SP3 where the first step layer STPL1 and the second step layer STPL2 are not arranged. The thickness TT1 of the optical auxiliary layer OAL in the first sub-pixel SP1 may be smaller than the thickness TT2 of the optical auxiliary layer OAL in the second sub-pixel SP2. Alternatively or additionally, the thickness TT1 of the optical auxiliary layer OAL in the first sub-pixel SP1 may be smaller than the thickness TT2 of the optical auxiliary layer OAL in the second sub-pixel SP2. Alternatively or additionally, the thickness TT2 of the optical auxiliary layer OAL in the second sub-pixel SP2 may be smaller than the thickness TT3 of the optical auxiliary layer OAL in the third sub-pixel SP3.

The thickness of the first step layer STPL1 may be equal to or different from the thickness of the second step layer STPL2. Depending on whether the first step layer STPL1 and the second step layer STPL2 is disposed and on the thickness, the thickness TT1 of the optical auxiliary layer OAL in the first sub-pixel SP1, the thickness TT2 of the optical auxiliary layer OAL in the second sub-pixel SP2, and the thickness TT3 of the optical auxiliary layer OAL in the third sub-pixel SP3 may be different from one another. Therefore, the thickness TT1 of the first step layer STPL1 and the thickness TT2 of the second step layer STPL2 may be determined, e.g., may be designed, based on the main peak wavelength of the first light, the main peak wavelength of the second light, the main peak wavelength of the third light, the distance from the first stack layer IL1 to the reflective electrode RL in the first emission area EA1, and the distance from the second stack layer IL2 to the reflective electrode RL in the second emission area EA2. Based on the thicknesses, the resonance distance of the first light, the resonance distance of the second light, and the resonance distance of the third light may be determined.

Although two step layers, e.g., the first step layer STPL1 and the second step layer STPL2 are shown in FIGS. 7 and 8, some example embodiments are not limited thereto. If the resonance distance of the first light, the resonance distance of the second light and the resonance distance of the third light can be optimally designed only with one step layer, either the first step layer STPL1 or the second step layer STPL2 may be eliminated.

Alternatively or additionally, although the first step layer STPL1 is disposed in the first sub-pixel SP1, and the second sub-pixel SP2 and the second step layer STPL2 are disposed in the first sub-pixel in FIGS. 7 and 8, some example embodiments are not limited thereto. The positions of the first step layer STPL1 and the second step layer STPL2 may also be determined based on the main peak wavelength of the first light, the main peak wavelength of the second light, the main peak wavelength of the third light, the distance from the first stack layer IL1 to the reflective electrode RL in the first emission area EA1, and the distance from the second stack layer IL2 to the reflective electrode RL in the second emission area EA2.

Each of the light-emitting elements LE may include a first electrode AND, an emission stack IL, and a second electrode CAT.

The first electrode AND of each of the light-emitting elements LE may be arranged on the side surfaces of the connection electrode ANC, the side surfaces of the reflective electrode RL, and the upper surface and the side surfaces of the optical auxiliary layer OAL. Since the first electrode AND of each of the light-emitting elements LE comes in contact with the side surfaces of the reflective electrode RL and the side surfaces of the connection electrode ANC and is electrically connected to them, it may be possible to reduce mask processes (e.g., photolithography processes) compared to the structure in which the first electrode AND of each of the light-emitting elements LE is connected to the reflective electrode RL exposed through a hole penetrating the optical auxiliary layer OAL. Alternatively or additionally, the fabrication cost can be saved and/or the fabrication efficiency can be increased.

Alternatively or additionally, since the thickness of the ninth insulating layer INS9 is greater in the first area AA1 than in the second area AA2, the ninth insulating layer INS9 may be partially exposed in the first area AA1. Therefore, the first electrode AND of each of the light-emitting elements LE may be located on a part of the ninth insulating layer INS9 in the first area AA1. Accordingly, the length of the first electrode AND in the third direction DR3 may be greater than the sum of the length of the side surfaces of the connection electrode ANC, the length of the side surfaces of the reflective electrode RL, and the length of the side surfaces of the optical auxiliary layer OAL.

The first electrode AND of each of the light-emitting elements LE may be connected to one of (e.g., only one of) the drain area DA or the source area SA of the pixel transistor PTR through the connection electrode ANC, the first to ninth via electrodes VA1 to VA9, the first to eighth metal layers ML1 to ML8 and the contact terminal CTE.

The first electrode AND of each of the light-emitting elements LE may be made of one or more of copper (Cu), aluminum (Al), tungsten (W), molybdenum (Mo), chromium (Cr), gold (Au), titanium (Ti), nickel (Ni) and neodymium (Nd), or an alloy containing at least one of these. For example, the first electrode AND of each of the light-emitting elements LE may be titanium nitride (TiN).

The thickness of the first electrode AND located on the upper surface of the optical auxiliary layer OAL may be smaller than the thickness of the first electrode AND located on the side surfaces of the connection electrode ANC, the side surfaces of the reflective electrode RL, and the side surfaces of the optical auxiliary layer OAL. Accordingly, the thickness of the first electrode AND located on the upper surface of the optical auxiliary layer OAL is approximately 50 Å or less, and thus the light transmittance of the first electrode AND located on the upper surface of the optical auxiliary layer OAL can be increased. Alternatively or additionally, the thickness of the first electrode AND located on the side surfaces of the connection electrode ANC, the side surfaces of the reflective electrode RL and the side surfaces of the optical auxiliary layer OAL ranges approximately from 100 Å to 200 Å, and thus it is possible to prevent or reduce the likelihood of and/or the impact in the contact resistance from increasing when the first electrode AND is in contact only with the side surfaces of the connection electrode ANC and the side surfaces of the reflective electrode RL.

The pixel-defining layer PDL may be located partially on the first electrode AND of each of the light-emitting elements LE. The pixel-defining layer PDL may cover the edge of the first electrode AND of each of the light-emitting elements LE. The pixel-defining layer PDL may define the first emission areas EA1, the second emission areas EA2 and the third emission areas EA3.

A first emission area EA1 may be defined as an area in the first sub-pixel SP1 where the first electrode AND, the emission stack IL, and the second electrode CAT are sequentially stacked on one another to emit light. A second emission area EA2 may be defined as an area in the second sub-pixel SP2 where the first electrode AND, the emission stack IL, and the second electrode CAT are sequentially stacked on one another to emit light. A third emission area EA3 may be defined as an area in the third sub-pixel SP3 where the first electrode AND, the emission stack IL, and the second electrode CAT are sequentially stacked on one another to emit light.

The pixel-defining layer PDL may include first to third pixel-defining layers PDL1, PDL,2 and PDL3.

The first pixel-defining layer PDL1 may be disposed on the first electrode AND of each of the light-emitting elements LE. Specifically, the first pixel-defining layer PDL1 may cover a part of the first electrode AND located on y upper surface of the optical auxiliary layer OAL. Alternatively or additionally, the first pixel-defining layer PDL1 may cover the first electrode AND which is disposed on the side surfaces of the connection electrode ANC, the side surfaces of the reflective electrode RL and the side surfaces of the optical auxiliary layer OAL. Alternatively or additionally, the first pixel-defining layer PDL1 may cover the first electrode AND that is located on a part of the ninth insulating layer INS9 in the first area AA1. The first pixel-defining layer PDL1 may be located on the second area AA2 of the ninth insulating layer INS9.

The planarization film PNS is or includes (or is included in) a film for providing a flat surface over the ninth insulating layer INS9, the connection electrode ANC, the first step layer STPL1, the second step layer STPL2, the reflective electrode RL and the optical auxiliary layer OAL. The planarization film PNS may be disposed between the connection electrodes ANC adjacent to each other in the first direction DR1 or the second direction DR2. The planarization film PNS may be located between the reflective electrodes RL adjacent to each other in the first direction DR1 or the second direction DR2. The planarization film PNS may be located between the optical auxiliary layer OAL adjacent to each other in the first direction DR1 or the second direction DR2. The planarization film PNS may be located on the first pixel-defining layer PDL1 located on the second area AA2 of the ninth insulating layer INS9.

The second pixel-defining layer PDL2 may be located on the first pixel-defining layer PDL1 and the planarization film PNS, and the third pixel-defining layer PDL3 may be located on the second pixel-defining layer PDL2. The first pixel-defining layer PDL1 and the third pixel-defining layer PDL3 may be made of an inorganic film such as a silicon nitride (SiNx) film, while the second pixel-defining layer PDL2 and the planarization film PNS may be made of an inorganic film such as a silicon oxide (SiOx) film. Since the first pixel-defining layer PDL1 is made of a different material from the planarization film PNS, it may work as a stopper in a process of chemically and mechanically polishing the planarization film PNS.

The thickness of the first pixel-defining layer PDL1, the second pixel-defining layer PDL2 and the third pixel-defining layer PDL3 may be, but is not limited to, approximately 500 Å.

When the first pixel-defining layer PDL1, the second pixel-defining layer PDL2 and the third pixel-defining layer PDL3 are formed as a single pixel-defining layer, the height of the single pixel-defining layer increases, and thus the second electrode CAT may be broken due to step coverage. Herein, the step coverage refers to a ratio of a thin film applied on an inclined portion to the thin film applied on a flat portion. The lower the step coverage is, the more likely it is that the thin film would break at the inclined portion.

In order to prevent or reduce the likelihood of and/or impact from the first inorganic encapsulation film TFE1 from breaking due to step coverage, the first pixel-defining layer PDL1, the second pixel-defining layer PDL2 and the third pixel-defining layer PDL3 may have a cross-sectional structure in the form of stairs or steps. For example, the width of the first pixel-defining layer PDL1 may be greater than the width of the second pixel-defining layer PDL2 and the width of the third pixel-defining layer PDL3, the width of the second pixel-defining layer PDL2 may be greater than the width of the third pixel-defining layer PDL3. The width of the first pixel-defining layer PDL1 refers to the horizontal length of the first pixel-defining layer PDL1 defined by the first direction DR1 or the second direction DR2.

Each of the plurality of trenches TRC may penetrate the first pixel-defining layer PDL1, the planarization film PNS, the second pixel-defining layer PDL2, and the third pixel-defining layer PDL3. Alternatively or additionally, the ninth insulating layer INS9 may be partially dug in each of the plurality of trenches TRC.

At least one trench TRC may be formed between the adjacent ones of the emission areas EA1, EA2, and EA3. Although two trenches TRC are formed between adjacent ones of the emission areas EA1, EA2, and EA3 in the example shown in FIGS. 7 and 8, example embodiments are not limited thereto.

The emission stack IL may include a plurality of stacks IL1, IL2, and IL3. Although the emission stack IL has a three-tandem structure including a first stack layer IL1, a second stack layer IL2 and a third stack layer IL3 in the example shown in FIGS. 7 and 8, example embodiments are not limited thereto. For example, the emission stack IL may have a two-tandem structure including two stack layers.

In a three-tandem structure, the emission stack IL may have a tandem structure including a plurality of stack layers IL1, IL2 and IL3 emitting different lights. For example, the emission stack IL may include the first stack layer IL1 that outputs the first light, the second stack layer IL2 that outputs the third light, and the third stack layer IL3 that outputs the second light. The first stack layer IL1, the second stack layer IL2 and the third stack layer IL3 may be sequentially stacked on one another.

The first stack layer IL1 may have a structure in which a first hole transport layer, a first organic emissive layer, and a first electron transport layer are sequentially stacked on one another. The second stack layer IL2 may have a structure in which a second hole transport layer, a second organic emissive layer, and a second electron transport layer are sequentially stacked on one another. The third stack layer IL3 may have a structure in which a third hole transport layer, a third organic emissive layer, and a third electron transport layer are sequentially stacked on one another.

The first organic emissive layer, the second organic emissive layer, and the third organic emissive layer may provide light in different wavelength ranges. For example, among the first to third organic emissive layers, an organic emissive layer may provide the first light, another organic emissive layer may provide the second light, and the other organic emissive layer may provide the third light.

A first charge generation layer may be arranged between the first stack layer IL1 and the second stack layer IL2 to supply charges to the second stack layer IL2 and electrons to the first stack layer IL1. The first charge generation layer may include an n-type charge generation layer that supplies electrons to the first stack layer IL1, and a p-type charge generation layer that supplies holes to the second stack layer IL2. The n-type charge generation layer may include a dopant of a metallic material.

A second charge generation layer may be located between the second stack layer IL2 and the third stack layer IL3 to supply charges to the third stack layer IL3 and electrons to the second stack layer IL2. The second charge generation layer may include an n-type charge generation layer that supplies electrons to the second stack layer IL2, and a p-type charge generation layer that supplies holes to the third stack layer IL3.

The first stack layer IL1 may be located on the first electrodes AND and the pixel-defining layer PDL. A residual layer RIL made of the same material as the first stack layer IL1 may be placed on the bottom surface of each of the trenches TRC. Due to the trenches TRC, the first stack layer IL1 may be disconnected between the adjacent sub-pixels SP1, SP2, and SP3. The second stack layer IL2 may be located on the first stack layer IL1. Due to the trenches TRC, the second stack layer IL2 may be disconnected between the adjacent sub-pixels SP1, SP2, and SP3. In each of the trenches TRC, void or empty space may be located between the residual layer RIL and the second stack layer IL2. The third stack layer IL3 may be disposed on the second stack layer IL2. The third stack layer IL3 may not be disconnected by the trenches TRC and may cover the second stack layer IL2 in each of the trenches TRC.

Therefore, in the three-tandem structure, each of the plurality of trenches TRC may be a feature for disconnecting the first charge generation layer and the second charge generation layer of the display element layer EML between the neighboring sub-pixels SP1, SP2, and SP3 in order to prevent or reduce the likelihood of and/or impact from electric current from flowing through the first charge generation layer and the second charge generation layer. Alternatively or additionally, in the two-tandem structure, each of the plurality of trenches TRC may be a feature for disconnecting a charge generation layer between a lower stack layer and an upper stack layer in order to prevent or reduce the likelihood of and/or impact from electric current from flowing through the charge generation layer.

In order to stably disconnect the first charge generation layer and the second charge generation layer of the display element layer EML between the adjacent ones of the emission areas EA1, EA2 and EA3, the height of each of the plurality of trenches TRC may be greater than the height of the pixel-defining layer PDL and the height of the planarization film PNS. The height of each of the plurality of trenches TRC refers to the length measured in the third direction DR3. The height of the pixel-defining layer PDL refer to the length of the pixel-defining layer PDL in the third direction DR3. The height of the planarization film PNS refers to the length of the planarization film PNS in the third direction DR3.

In order to disconnect the first charge generation layer and the second charge generation layer of the display element layer EML, there may be other features than the trenches TRC between the adjacent ones of the emission areas EA1, EA2 and EA3. For example, instead of or in addition to the trenches TRC, partition walls in the form of an inverse taper may be arranged on the pixel-defining layer PDL.

The second electrode CAT may be located on the emission stack IL. The second electrode CAT may be located on the third stack layer IL3 in each of a plurality of trenches TRC. The second electrode CAT may be formed as a semi-transmissive conductive material such as magnesium (Mg), silver (Ag), or an alloy of magnesium (Mg) and silver (Ag). In this instance, the light extraction efficiency can be increased by using microcavities in each of the first to third sub-pixels SP1, SP2, and SP3.

The encapsulation layer TFE may be located on the display element layer EML. The encapsulation layer TFE may include one or more inorganic films TFE1 and TFE2 to prevent or reduce the likelihood of and/or impact from permeation of oxygen and/or moisture into the display element layer EML. For example, the encapsulation layer TFEL may include a first inorganic encapsulation film TFE1 and a second inorganic encapsulation film TFE2.

The first inorganic encapsulation film TFE1 may be located on the second electrode CAT. The first inorganic encapsulation film TFE1 may be made up of multiple films in which one or more inorganic films of silicon nitride (SiNx), silicon oxynitride (SiON) and a silicon oxide (SiOx) are alternately stacked on one another. The first inorganic encapsulation film TFE1 may be formed via a chemical vapor deposition (CVD) process.

The second inorganic encapsulation film TFE2 may be located on the first inorganic encapsulation film TFE1. The second inorganic encapsulation film TFE2 may be formed of titanium oxide (TiOx) or aluminum oxide layer (AlOx), but example embodiments are not limited thereto. The second inorganic encapsulation film TFE2 may be formed via an atomic layer deposition (ALD) process. The thickness of the second inorganic encapsulation film TFE2 may be smaller than the thickness of the first inorganic encapsulation film TFE1.

An organic film APL may be a layer to increase the interfacial adhesion between the encapsulation layer TFE and the optical layer OPL. The organic film APL may be or may include an acryl resin, an epoxy resin, a phenolic resin, a polyamide resin, and/or a polyimide resin.

The optical layer OPL includes a plurality of color filters CF1, CF2 and CF3, a plurality of lenses LNS, and a filling layer FIL. The plurality of color filters CF1, CF2 and CF3 may include first to third color filters CF1, CF2 and CF3. The first to third color filters CF1, CF2 and CF3 may be arranged on the adhesive layer ADL.

The first color filter CF1 may be in line with the first emission area EA1 of the first sub-pixel SP1. The first color filter CF1 may transmit first light, e.g., light in the red wavelength range. Therefore, the first color filter CF1 may transmit the first light among the lights emitted from the emission stack IL of the first emission area EA1.

The second color filter CF2 may be in line with the second emission area EA2 of the second sub-pixel SP2. The second color filter CF2 may transmit second light, e.g., light in the green wavelength range. Therefore, the second color filter CF2 may transmit the second light among the lights emitted from the emission stack IL of the second emission area EA2.

The third color filter CF3 may be in line with the third emission area EA3 of the third sub-pixel SP3. The third color filter CF3 may transmit third light, e.g., light in the blue wavelength range. Therefore, the third color filter CF3 may transmit the third light among the lights emitted from the emission stack IL of the third emission area EA3.

The lenses LNS may be arranged on the first color filter CF1, the second color filter CF2 and the third color filter CF3, respectively. Each of the lenses LNS may be a structure for increasing the ratio of light directed to the front side of the display device 10. Each of the lenses LNS may have a cross-sectional shape that is convex upward. It should be understood, however, that example embodiments are not limited thereto.

The filling layer FIL may be located on a plurality of lenses LNS. The filling layer FIL may have a predetermined refractive index so that light travels in the third direction DR3 at the interface between the plurality of lenses LNS and the filling layer FIL. Alternatively or additionally, the filling layer FIL may be or may include a planarization layer. The filling layer FIL may be an organic film such as an acryl resin, an epoxy resin, a phenolic resin, a polyamide resin, and a polyimide resin.

The cover layer CVL may be located on the filling layer FIL. The cover layer CVL may be a glass substrate or a polymer resin such as a resin. If the cover layer CVL is a glass substrate, it may be attached to the filling layer FIL. In this instance, the filling layer FIL may adhere the cover layer CVL. If the cover layer CVL is a glass substrate, it may work as an encapsulation substrate. If the cover layer CVL is a polymer resin such as a resin, it may be applied directly on the filling layer FIL.

A polarizer POL may be located on a surface of the cover layer CVL. The polarizer POL may be a structure for preventing or reducing the likelihood of and/or impact from deterioration of visibility due to reflection of external light. The polarizer POL may include a linear polarizer and a retardation film. For example, the retardation film may be a λ/4 plate (quarter-wave plate), but some example embodiments are not limited thereto. If visibility is sufficiently improved by the first to third color filters CF1, CF2, and CF3 regardless of reflection of external light, the polarizer POL may be eliminated.

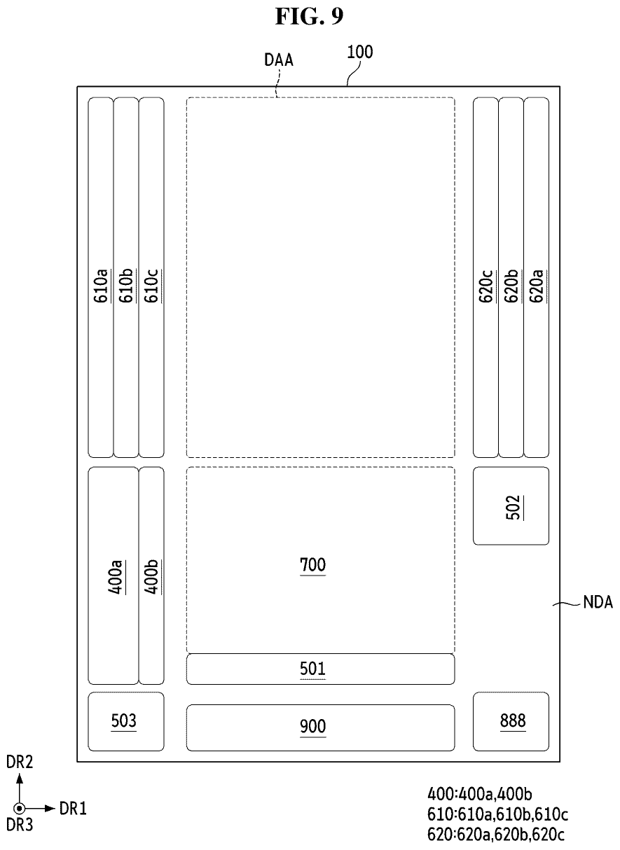

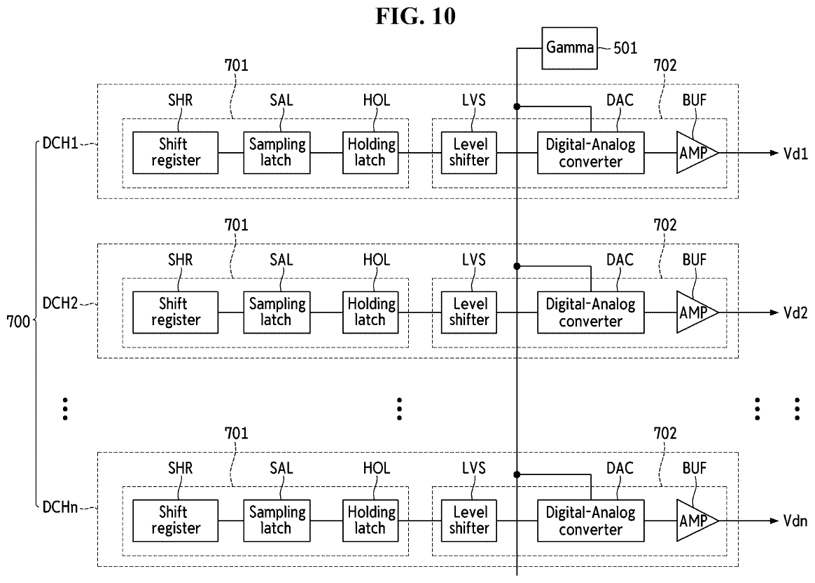

FIG. 9 is a layout diagram of a display panel 100 according to some example embodiments. FIG. 10 is a block diagram of the data driver 700 of FIG. 9.

The scan driver 610 may include a scan shift register 610a, a scan level shifter 610b, and a scan buffer 610c.

The scan shift register 610a may receive a scan shift clock and a scan start pulse from the timing control circuit 400, and may sequentially generate a plurality of scan signals by shifting the scan start pulse every cycle of the scan shift clock.

The scan level shifter 610b may convert the levels of the scan signals from the scan shift register 610a and may provide them to the scan buffer 610c.

The scan buffer 610c may buffer the scan signals from the scan level shifter 610b to output them.

The emission driver 620 may include an emission shift register 620a, an emission level shifter 620b, and an emission buffer 620c.

The emission shift register 620a may receive an emission shift clock and an emission start pulse from the timing control circuit 400, and may sequentially generate a plurality of emission control signals by shifting the emission start pulse every cycle of the emission shift clock.

The emission level shifter 620b may convert the levels of the emission control signals from the emission shift register 620a and may provide them to the emission buffer 620c.

The emission buffer 620c may buffer the emission signals from the emission level shifter 620b to output them.

A gamma circuit 501 may generate a plurality of grayscale values or grayscale voltages by dividing a gamma reference voltage and may provide the generated grayscale voltages to the data driver 700. For example, the gamma circuit 501 may generate red grayscale voltages for red image data, green grayscale voltages for green image data, and blue grayscale voltages for blue image data.

An interface circuit 900 may convert serial image data from the outside into parallel image data and may provide them to the data drive 700.

The data driver 700 may include a plurality of channel circuits DCH1, DCH2, and DCHn (e.g., data channel circuits), as shown in FIG. 10.

The channel circuits DCH1, DCH2 and DCHn may output a plurality of data voltages Vd1, Vd2, and Vdn. For example, the first channel circuit DCH1 may output the first data voltage Vd1, the second channel circuit DCH2 may output the second data voltage Vd2, and the n^{th} channel circuit DCHn may output the n^{th} data voltage Vdn, where n may be a natural number equal to or greater than two.

The channel circuits DCH1, DCH2 and DCHn may be respectively connected to the data lines DL, respectively. For example, the first channel circuit DCH1 may be connected to a first data line, the second channel circuit DCH2 may be connected to a second data line, and the n^{th} channel circuit DCHn may be connected to the n^{th} data line. The first data voltage Vd1 from the first channel circuit DCH1 may be applied to the first data line, the second data voltage Vd2 from the second channel circuit DCH2 may be supplied to the second data line, and the n^{th} data voltage Vdn from the n^{th} channel circuit DCHn may be applied to the n^{th} data line.

Each of the channel circuits DCH1, DCH2 and DCHn may include a data processing circuit 701 and a data output circuit 702.

The data processing circuit 701 may process digital image data signals from the timing control circuit 400 and provide them to the data output circuit 702. The data processing circuit 701 may include a shift register SHR (e.g., a data shift register), a sampling latch SAL (e.g., a data sampling latch), and a holding latch HOL (e.g., a data holding latch).

The data output circuit 702 may convert an image data signal from the data processing circuit 701 into an analog signal and provide it to a data line DL. The data output circuit 702 may include a level shifter LVS (e.g., a data level shifter), a digital-to-analog converter DAC (e.g., a data digital-to-analog converter), and a buffer BUF (e.g., a data buffer). The buffer BUF may be connected to the data line DL through the first distribution circuit 710.

The shift register SHR may receive a source shift clock and a source start pulse from the timing control circuit 400, and may sequentially generate a plurality of sampling signals by shifting the source start pulse every cycle of the source shift clock.

The sampling latch SAL may sequentially store digital image data signals in response to sampling signals sequentially provided from the shift register SHR.

The holding latch HOL may receive and store the image data signals from the sampling latch SAL in response to a source output enable signal and may output a sampled image data signal that was stored in a previous period. The image data signal output from the holding latch HOL may be provided to the digital-to-analog converter DAC through the level shifter LVS.

The level shifter LVS may convert the level of an image data signal from the holding latch HOL and may provide it to the digital-to-analog converter DAC. For example, the level shifter LVS may convert the level of an image data signal so that the image data signal has a level that can drive the transistors of the digital-to-analog converter DAC.

The digital-to-analog converter DAC may provide an analog image data signal corresponding to the bit value of the image data signal provided from the holding latch HOL through the level shifter LVS. For example, the digital-to-analog converter DAC may select a grayscale voltage from the gamma circuit 501 that corresponds to the bit value of the digital image data signal from the holding latch HOL and output the selected grayscale voltage as an analog image data signal.

The buffer BUF may receive a grayscale voltage (e.g., an analog image data signal) from the digital-to-analog converter DAC and may amplify the grayscale voltage to output it. The grayscale voltage from the buffer BUF may be provided to the data line DL. The buffer BUF may include an amplifier.

The timing control circuit 400 may include a first timing controller 400a and a timing buffer 400b.

The first timing controller 400a may output the source shift clock, the source start pulse, the source output enable signal, the scan shift clock, the scan start pulse, the emission shift clock, and the emission start pulse.

The timing buffer 400b may buffer signals from the first timing controller 400a and provide them to the scan driver 610, the emission driver 620, and the data driver 700.

The second timing controller 502 may control the input timing of the grayscale voltage supplied from the gamma circuit 501 to the digital-to-analog converter DAC.

A sensor circuit 888 may include a circuit for driving a touch sensor of the display panel 100.

A regulator 503 may generate a variety of powers required for driving the display panel 100. The regulator 503 may be included in the power supply circuit 500.

The gamma circuit 501 may be commonly connected to the digital-to-analog converter DAC of each of the channel circuits DCH1, DCH2 and DCHn. For example, the gamma circuit 501 may be commonly connected to a plurality of digital-to-analog converters DAC. Accordingly, grayscale voltages (e.g., grayscale voltages of grayscale levels from 0 to 255) from the gamma circuit 501 may be commonly provided to the digital-to-analog converters DAC. Alternatively according to some example embodiments, there may be a plurality of gamma circuits. For example, a plurality of gamma circuits may be connected to a plurality of digital-to-analog converters DAC. The number of the gamma circuits may be smaller than the number of the digital-to-analog converters DAC. In this instance, one gamma circuit may be commonly connected to some of the digital-to-analog converters DAC, and another gamma circuit may be commonly connected to some others of the digital-to-analog converters DAC.

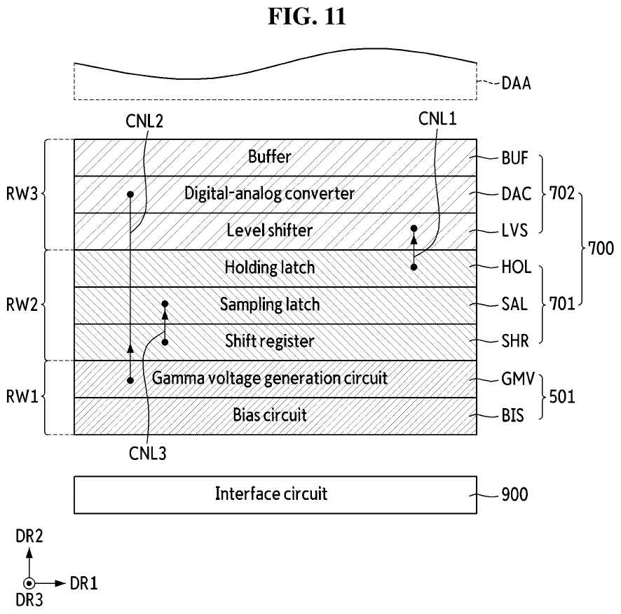

FIG. 11 is a view for illustrating the positions of a data processing circuit 701, a data output circuit 702 and a gamma circuit 501 of a display device according to some example embodiments. For example, FIG. 11 may be a view for illustrating the positions of the data processing circuit 701, the data output circuit 702 and the gamma circuit 501 of the display device of FIG. 9.

As shown in FIG. 11, the gamma circuit 501 may include a gamma voltage generation circuit GMV and a bias circuit BIS.

The gamma voltage generation circuit GMV may generate a plurality of grayscale voltages by dividing a gamma reference voltage and may provide the generated grayscale voltages to the data driver 700.

The bias circuit BIS may provide power to the gamma voltage generation circuit GMV. For example, the bias circuit BIS may provide a variety of powers, including a gamma reference voltage, to the gamma voltage generation circuit GMV.

Referring to FIGS. 9 and 11, the gamma circuit 501 and the data driver 700 may be located between one side of the display panel 100 and the display area DAA in the non-display area NDA. For example, the gamma circuit 501 and the data driver 700 may be placed between the interface circuit 900 and the display area DAA in the non-display area NDA.

The gamma circuit 501, the data processing circuit 701 and the data output circuit 702 may be arranged in different rows. For example, the gamma circuit 501 may be located in a first row RW1 in the non-display area NDA between the interface circuit 900 and the display area DAA, the data processing circuit 701 may be located in a second row RW2, and the data output circuit 702 may be located in a third row RW3. The rows RW1, RW2, and RW3 may be extended in the first direction, and the rows RW1, RW2 and RW3 may be arranged in the second direction DR2.

In the non-display area NDA between an edge of the display panel 100 (e.g., the interface circuit 900) and the display area DAA, the gamma circuit 501, the data processing circuit 701 and the data output circuit 702 may be sequentially arranged along the second direction DR2 from the edge of the display panel 100 (e.g., the interface circuit 900). Accordingly, among the above-described elements 501, 701 and 702, the gamma circuit 501 may be closest to the interface circuit 900, and the data output circuit 702 may be farthest from the interface circuit 900. For example, among the above-described elements 501, 701 and 702, the gamma circuit 501 may be furthest from the display area DAA, and the data output circuit 702 may be closest to the display area DAA.

The data processing circuit 701 may be located between the gamma circuit 501 and the data output circuit 702.

The gamma circuit 501 and the data processing circuit 701 may be adjacent to each other in the second direction DR2.

The data processing circuit 701 and the data output circuit 702 may be adjacent to each other in the second direction DR2.

In the non-display area NDA between an edge of the display panel 100 (e.g., the interface circuit 900) and the display area DAA, the bias circuit BIS, the gamma voltage generation circuit GMV, the shift register SHR, the sampling latch SAL, the holding latch HOL, the level shifter LVS, the digital-to-analog converter DAC and the buffer BUF may be sequentially arranged in the second direction DR2 from the edge of the display panel 100 (e.g., the interface circuit 900). Accordingly, among the above-described elements BIS, GMV, SHR, SAL, LVS, DAC and BUF, the bias circuit BIS may be closest to the interface circuit 900, and the buffer BUF may be farthest from the interface circuit 900. In other words, among the above-described elements BIS, GMV, SHR, SAL, LVS, DAC and BUF, the bias circuit BIS may be farthest from the display area DAA, and the buffer BUF may be closest to the display area DAA.

The gamma voltage generation circuit GMV and the shift register SHR may be adjacent to each other in the second direction DR2.

The holding latch HOL and the level shifter LVS may be adjacent to each other in the second direction DR2.

The holding latch HOL and the level shifter LVS adjacent to each other may be electrically connected to each other by a first connection line CNL1. For example, one side of the first connection line CNL1 may be connected to the holding latch HOL, while the opposite side of the first connection line CNL1 may be connected to the level shifter LVS. An image data signal output from the holding latch HOL may be provided to the level shifter LVS through the first connection line CNL1. The first connection line CNL1 may be located in the same layer as the seventh conductive layer ML7. For example, the first connection line CNL1 may be arranged on the seventh insulating layer INS7. In this instance, the first connection line CNL1 may be made of the same material as the seventh conductive layer ML7.

The gamma voltage generation circuit GMV and the digital-to-analog converter DAC, which are spaced apart from each other, may be electrically connected with each other via a second connection line CNL2. For example, one side of the second connection line CNL2 may be connected to the gamma voltage generation circuit GMV, and the opposite side of the second connection line CNL2 may be connected to the digital-to-analog converter DAC. Grayscale voltages output from the gamma voltage generation circuit GMV may be provided to the digital-to-analog converter DAC via the second connection line CNL2. The second connection line CNL2 may overlap with the shift register SHR, the sampling latch SAL, the holding latch HOL, and the level shifter LVS. The second connection line CNL2 and the first connection line CNL1 may be arranged on different layers. For example, the second connection line CNL2 may be arranged on the same layer as the eighth conductive layer ML8. For example, the second connection line CNL2 may be arranged on the eighth insulating layer INS8. In this instance, the second connection line CNL2 may be made of the same material as the eighth conductive layer ML8.

The first connection line CNL1 and the second connection line CNL2 may be provided for each of the channel circuits DCHn 1, DCH2, . . . , DCHn. For example, when the data driver 700 includes n channel circuits DCHn 1, DCH2, . . . , DCHn, the display device 10 may include n first connection lines CNL1 and n second connection lines CNL2.

The conductive layers used for the electrical connection between the data driver 700 and the gamma circuit 501, the electrical connection between the elements SHR, SAL, HOL, LVS, DAC and BUF of the data driver 700, and the electrical connection between the elements BIS and GMV of the gamma circuit 501 may be different from the conductive layers used in the above-described connection lines CNL1 and CNL2. For example, the electrical connection between the bias circuit BIS and the gamma voltage generation circuit GMV, the electrical connection between the shift register SHR and the sampling latch SAL, the electrical connection between the sampling latch SAL and the holding latch HOL, the electrical connection between the holding latch HOL and the level shifter LVS, the electrical connection between the level shifter LVS and the digital-to-analog converter DAC, and the electrical connection between the digital-to-analog converter DAC and the buffer BUF may be made through the first to sixth conductive layers ML1 to ML6. As an example, the shift register SHR and the sampling latch SAL may be electrically connected with each other by a third connection line CNL3, and thus the third connection line CNL3 may be made of the same material as one of the first to sixth conductive layers ML1 to ML6. The third connection line CNL3 may be arranged in the same layer as one of the first to sixth conductive layers ML1 to ML6. The third connection line CNL3 may deliver multiple sampling signals from the shift register SHR to the sampling latch SAL.

The thickness of the first connection line CNL1 may be equal to the thickness of the seventh conductive layer ML7, and the thickness of the second connection line CNL2 may be equal to the thickness of the eighth conductive layer ML8; example embodiments are not limited thereto.

The thickness of the third connection line CNL3 may be equal to the thickness of one of the first to sixth conductive layers ML1 to ML6; example embodiments are not limited thereto.

The thickness of the first connection line CNL1 may be greater than the thickness of the third connection line CNL3, and the thickness of the second connection line CNL2 may be greater than the thickness of the third connection line CNL3; example embodiments are not limited thereto.

According to some example embodiments, at least some elements of the gamma circuit 501 may be located in a different row from the data output circuit 702. For example, as shown in FIGS. 9 and 11, the gamma circuit 501 may be located in the first row RW1, and the data output circuit 702 may be located in the third row RW3. Accordingly, compared to a structure in which the gamma circuit 501 and the data output circuit 702 are arranged in the same row, the available area (or extra area) in which the data output circuit 702 may be arranged in the first direction DR1 in the non-display area NDA may increase. Accordingly, even in a high-resolution display panel 100 in which a large number of pixels PX and data lines DL are arranged along the first direction DR1 in the display area DAA, the size of the data output circuit 702 in the first direction DR1 can be sufficiently obtained. Therefore, according to some example embodiments, the data output circuit 702 may be arranged (or formed) on the high-resolution display panel 100 without reducing the channel width. As used herein, the channel width may refer to the distance between output terminals of the output circuit.

Alternatively or additionally, according to some example embodiments, since the gamma circuit 501 and the data output circuit 702 arranged in the different rows are connected with each other by routing lines (e.g., the third connection lines CNL3) that utilize the first to sixth conductive layers ML1 to ML6 and other lines (e.g., the second connection line CNL2), even though the gamma circuit 501 and the data output circuit 702 are arranged in the different rows, the electrical connection between the gamma circuit 501 and the data output circuit 702 can be easily made.

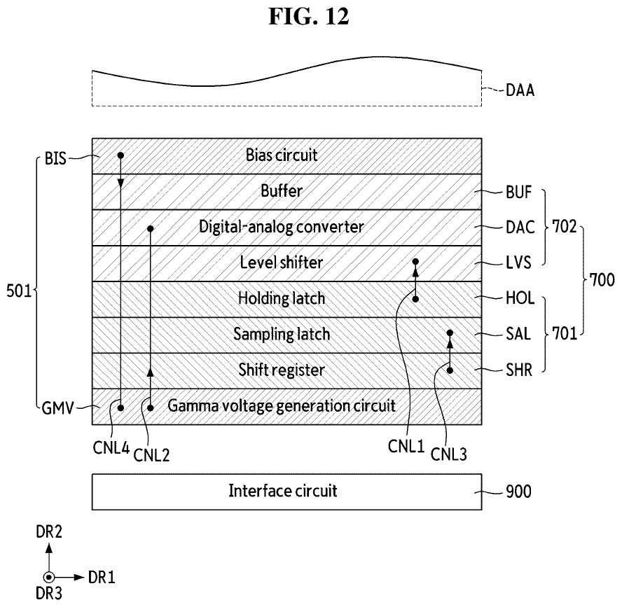

FIG. 12 is a view for illustrating the positions of a data processing circuit 701, a data output circuit 702 and a gamma circuit 501 of a display device 10 according to another embodiment. For example, FIG. 12 may be a view for illustrating the positions of the data processing circuit 701, the data output circuit 702 and the gamma circuit 501 of the display device 10 of FIG. 9.

A display device 10 of FIG. 12 is different from the above-described display device 10 of FIG. 6 in the position of a bias circuit BIS. The following description will focus on the difference.

As shown in FIG. 12, in the non-display area NDA between an edge of the display panel 100 (e.g., the interface circuit 900) and the display area DAA, the gamma voltage generation circuit GMV, the shift register SHR, the sampling latch SAL, the holding latch HOL, the level shifter LVS, the digital-to-analog converter DAC, the buffer BUF and the bias circuit BIS may be sequentially arranged in the second direction DR2 from the edge of the display panel 100 (e.g., the interface circuit 900). Accordingly, among the above-described elements BIS, GMV, SHR, SAL, LVS, DAC and BUF, the gamma voltage generation circuit GMV may be closest to the interface circuit 900, and the bias circuit BIS may be farthest from the interface circuit 900. In other words, among the above-described elements BIS, GMV, SHR, SAL, LVS, DAC and BUF, the gamma voltage generation circuit GMV may be farthest from the display area DAA, and the bias circuit BIS may be closest to the display area DAA.

The bias circuit BIS may be spaced apart from the gamma voltage generation circuit GMV.

The bias circuit BIS and the gamma voltage generation circuit GMV, which are spaced apart from each other, may be electrically connected with each other by a fourth connection line CNL4. For example, one side of the fourth connection line CNL4 may be connected to the bias circuit BIS, and the opposite side of the fourth connection line CNL4 may be connected to the gamma voltage generation circuit GMV. A voltage (e.g., a gamma reference voltage) output from the bias circuit BIS may be provided to the gamma voltage generation circuit GMV through the fourth connection line CNL4. The fourth connection line CNL4 may overlap with the shift register SHR, the sampling latch SAL, the holding latch HOL, the level shifter LVS, the digital-to-analog converter DAC and the buffer BUF. The fourth connection line CNL4 may be arranged in the same layer as either the first connection line CNL1 or the second connection line CNL2. For example, the fourth connection line CNL4 may be arranged in the same layer as the first connection line CNL1. In this instance, the fourth connection line CNL4 may be made of the same material as the first connection line CNL1. For example, the fourth connection line CNL4 may be arranged in the same layer as the seventh conductive layer ML7 and may be made of the same material as the seventh conductive layer ML7.

The data processing circuit 701, the data output circuit 702 and the gamma circuit 501 may be driven in different voltage regions. For example, the data output circuit 701 and the gamma circuit 501 may be driven in a lower voltage region than the data processing circuit 702. As an example, the data processing circuit 701 may be driven in a low-voltage region, while the data output circuit 702 and the gamma circuit 501 may be driven in a medium-voltage region (or a high-voltage region). As a specific example, the shift register SHR, the sampling latch SAL and the holding latch HOL may each be driven in a low-voltage region, while the digital-to-analog converter DAC, the buffer BUF, the bias circuit BIS and the gamma voltage generation circuit GMV may each be driven in a medium-voltage region (or a high-voltage region).

The display device 10 according to some example embodiments may be applied to a variety of electronic devices. An electronic device according to an embodiment includes the display device 10 described above, and may further include a module or device having additional features in addition to the display device 10.

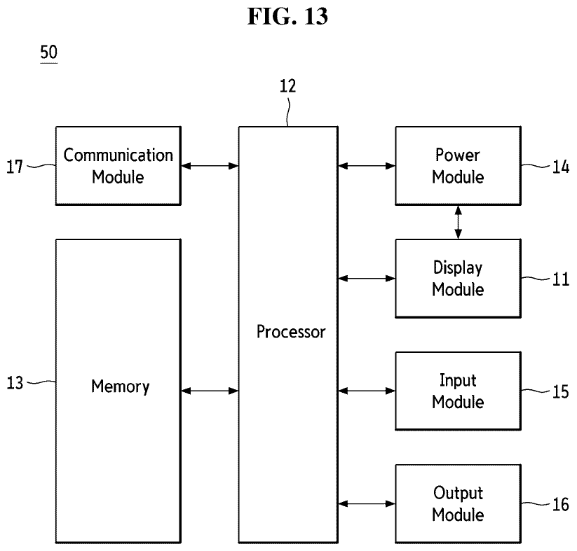

FIG. 13 is a block diagram of an electronic device according to some example embodiments.

Referring to FIG. 13, an electronic device 50 according to some example embodiments may include a display module 11, a processor 12, a memory 13, and a power module 14. The electronic device 50 may further include an input module 14, a non-image output module 15, and/or a communication module 16.

The electronic device 50 may output various information in the form of images through the display module 11. When the processor 12 executes an application stored in the memory 13, image information provided by the application may be provided to the user through the display module 11. The power module 14 may include a power supply module such as a power adapter and a battery device, and a power conversion module that converts the power supplied by the power supply module to generate power required for the operation of the electronic device 50. The input module 14 may provide input information to the processor 12 and/or the display module 11. The non-image output module 15 may receive information other than images from the processor 12, such as sound, haptic and light information, and provide it to the user. The communication module 16 is responsible for transmitting and receiving information between the electronic device 50 and an external device, and may include a receiving unit and a transmitting unit.

At least one of the elements of the electronic device 50 described above may be included in the display devices according to some example embodiments described above. Alternatively or additionally, some of the individual modules functioning as a single module may be included in the display device while some others may be provided separately from the display device. For example, the display device may include the display module 11, and the processor 12, the memory 13 and the power module 14 may be implemented as other devices inside the electronic device 50 instead of the display device.

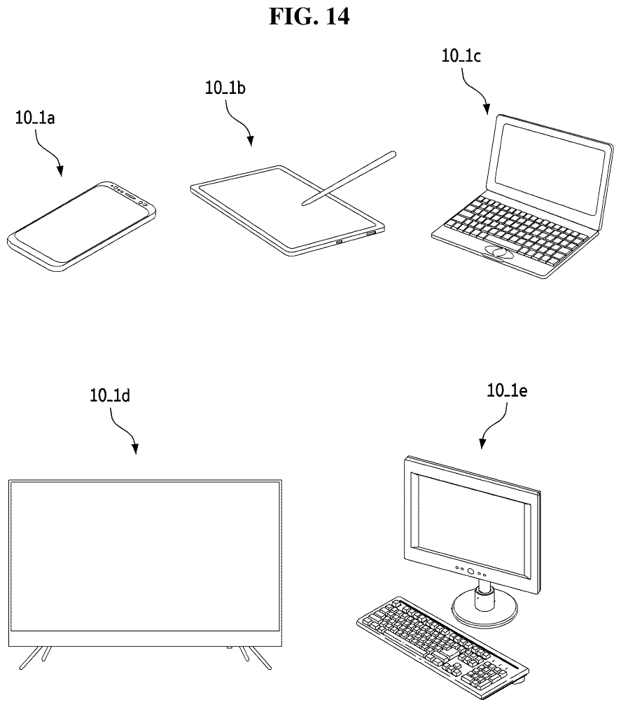

FIGS. 14, 15 and 16 are views showing electronic devices according to a variety of embodiments of the present disclosure. FIGS. 14 to 16 show examples of a variety of electronic devices employing the display devices 10 according to some example embodiments.

FIG. 14 shows a smartphone 10_1a, a tablet PC 10_1b, a laptop computer 10_1c, a TV 10_1d, and a desktop monitor 10_1e as examples of the electronic devices.

The smartphone 10_1a may include an input module such as a touch sensor and a communication module in addition to a display module 11. The smartphone 10_1a may process information received through the communication module or other input modules and display the information through the display module of the display device.

The tablet PCs 10_1b, the laptop computer 10_1c, the TV 10_1d and the desktop monitor 10_1e may include display modules and input modules similar to the smartphone 10_1a, and may further include communication modules as desired.

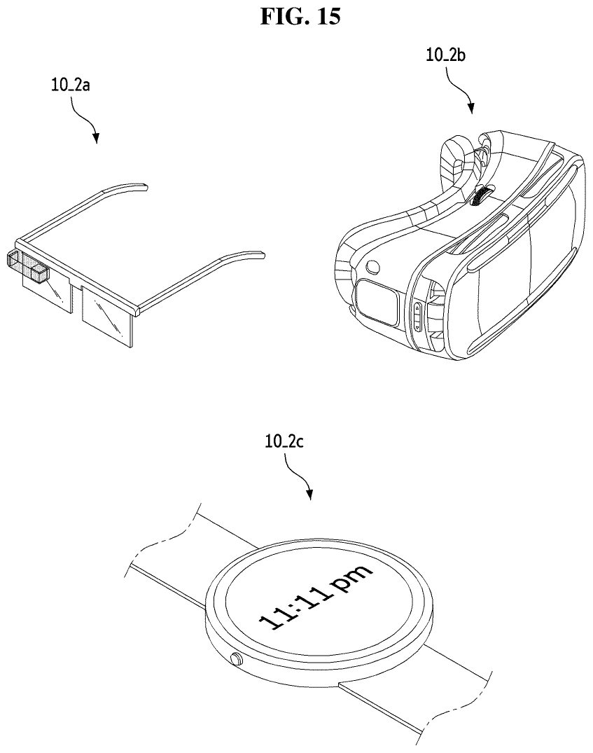

FIG. 15 shows examples of a wearable electronic device employing an electronic device including a display module. The wearable electronic devices may be smart glasses 10_2a, a head-mounted display 10_2b, a smart watch 10_2c, etc.

The smart glasses 10_2a and the head-mounted display 10_2b may include a display module that outputs display images, and a reflector that reflects the output display images and provides the reflected output display images to the user's eyes, thereby providing the user with images of virtual reality or augmented reality on the screen.

The smart watch 10_2c may include a biometric sensor as an input device, and may provide the user with biometric information recognized by the biometric sensor through the display module.

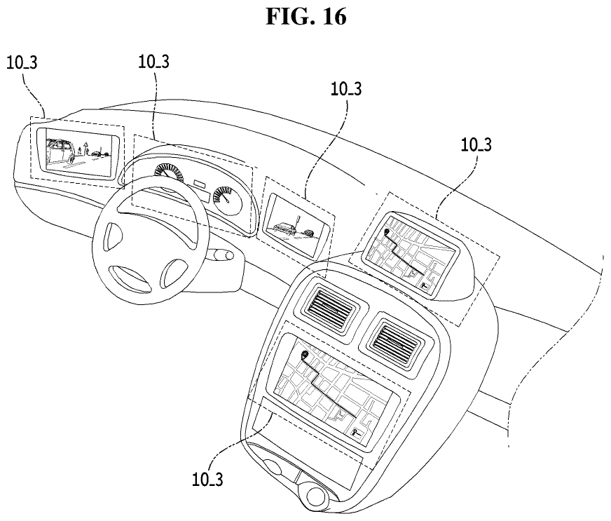

FIG. 16 shows an example of an electronic device including a display module applied to a vehicle. For example, an electronic device 10_3 may be applied to one or more of the instrument cluster, the center fascia, etc., of a vehicle, or may be applied to a center information display (CID) located at the dashboard of a vehicle, and/or may be used as a room mirror display on the behalf of the side mirrors of a vehicle.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

In concluding the detailed description, those of ordinary skill in the art will appreciate that many variations and modifications can be made to some example embodiments without substantially departing from the principles of inventive concepts. Therefore, the disclosed example embodiments of inventive concepts are used in a generic and descriptive sense only and not for purposes of limitation. Additionally, example embodiments are not necessarily mutually exclusive with one another. For example, some example embodiments may include one or more features described with reference to one or more figures, and may also include one or more other features described with reference to one or more other figures.

What is claimed is:

1. A display device comprising:
a display panel comprising a display area and a non-display area;
a data driver in the non-display area of the display panel and connected to a data line in the display area;
a gamma circuit in the non-display area of the display panel and connected to the data driver; and
a first connection line connecting the gamma circuit with the data driver, wherein
the data driver comprises a data processing circuit, and a data output circuit connected to the data processing circuit and the data line,
the data output circuit and the gamma circuit are in different rows in the non-display area,
the gamma circuit and the data output circuit are connected with each other by the first connection line, and
the first connection line at least partially overlaps the data processing circuit.

2. The display device of claim 1, wherein the data processing circuit comprises:
a shift register;
a sampling latch connected to the shift register; and
a holding latch connected to the sampling latch and the data output circuit.

3. The display device of claim 2, wherein the data output circuit comprises:
a level shifter connected to the sampling latch;
a digital-to-analog converter connected to the level shifter; and
a buffer connected to the digital-to-analog converter and the data line.

4. The display device of claim 3, wherein the gamma circuit comprises:
a bias circuit; and
a gamma voltage generation circuit connected to the bias circuit and the digital-to-analog converter.

5. The display device of claim 4, wherein the first connection line at least partially overlaps the shift register, at least partially overlaps the sampling latch, and at least partialy overlaps the holding latch.

6. The display device of claim 5, further comprising:
a second connection line connecting the shift register with the sampling latch.

7. The display device of claim 6, wherein the first connection line and the second connection line are in different layers.

8. The display device of claim 6, wherein a thickness of the first connection line is greater than a thickness of the second connection line.

9. The display device of claim 5, further comprising:
a third connection line connecting the holding latch with the level shifter.

10. The display device of claim 9, wherein the first connection line and the third connection line are in different layers.

11. The display device of claim 10, wherein a thickness of the first connection line is equal to a thickness of the third connection line.

12. The display device of claim 4, wherein the bias circuit, the gamma voltage generation circuit, the shift register, the sampling latch, the holding latch, the level shifter, the digital-to-analog converter, and the buffer are sequentially arranged from an edge of the display panel in the non-display area between the display area and the edge of the display panel.

13. The display device of claim 4, wherein the gamma voltage generation circuit, the shift register, the sampling latch, the holding latch, the level shifter, the digital-to-analog converter, the buffer, and the bias circuit are sequentially arranged from an edge of the display panel in the non-display area between the display area and the edge of the display panel.

14. The display device of claim 4, wherein the data output circuit and the gamma circuit are configured to operate in a lower-voltage range than the data processing circuit.

15. The display device of claim 14, wherein the shift register, the sampling latch and the holding latch are each configured to be driven in a low-voltage region, while the digital-to-analog converter, the buffer, the bias circuit and the gamma voltage generation circuit are each configured to be driven in a medium-voltage region higher than the low-voltage region.

16. An electronic device comprising:
a display device configured to provide at least one image on a display screen,
wherein the display device comprises,
a display panel comprising a display area and a non-display area,
a data driver in the non-display area of the display panel and connected to a data line in the display area,
a gamma circuit in the non-display area of the display panel and connected to the data driver, and
a first connection line connecting the gamma circuit with the data driver, wherein
the data driver comprises a data processing circuit, and a data output circuit connected to the data processing circuit and the data line,
the data output circuit and the gamma circuit are arranged in different rows in the non-display area,
the gamma circuit and the data output circuit are connected with each other by the first connection line, and
the first connection line at least partially overlaps the data processing circuit.

17. The electronic device of claim 16, wherein the data processing circuit comprises:
a shift register;
a sampling latch connected to the shift register; and
a holding latch connected to the sampling latch and the data output circuit.

18. The electronic device of claim 17, wherein the data output circuit comprises:
a level shifter connected to the sampling latch;
a digital-to-analog converter connected to the level shifter; and
a buffer connected to the digital-to-analog converter and the data line.

19. The electronic device of claim 18, wherein the gamma circuit comprises:
a bias circuit; and
a gamma voltage generation circuit connected to the bias circuit and the digital-to-analog converter.

20. The electronic device of claim 16, wherein the electronic device comprises at least one of a smartphone, a tablet PC, a laptop computer, a TV, a desktop monitor, smart glasses, a smart watch, a head-mounted display, or a display for vehicles.
